(19) United States
(12) Patent Application Publication
(10) Pub. No.: US 2009/0039408 A1
(43) Pub. Date: Feb. 12, 2009

(54) NONVOLATILE SEMICONDUCTOR MEMORY AND MANUFACTURING METHOD THEREOF

(76) Inventors: Tomoaki Hatano, Yokohama-shi (JP); Toshifumi Minami, Yokohama-shi (JP); Norihisa Arai, Saitama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/187,679

(22) Filed: Aug. 7, 2008

(30) Foreign Application Priority Data
Aug. 9, 2007 (JP) 2007-208297

(51) Int. Cl. H01L 27/115; H01L 21/8247

(52) U.S. Cl. 257/316; 438/258; 257/E27.103; 257/E21.691

(57) ABSTRACT

A nonvolatile semiconductor memory of an aspect of the present invention comprises a first element isolation insulating film containing an organic substance which surrounds a first region, a memory cell arranged in the first region, a second element isolation insulating film containing an organic substance which surrounds a second region, a peripheral transistor arranged in the second region, and a first impurity layer which is provided in the semiconductor substrate along a side surface of the second element isolation insulating film.

### CROSS-REFERENCE TO RELATED APPLICATIONS

This application is based upon and claims the benefit of priority from prior Japanese Patent Application No. 2007-208297, filed Aug. 9, 2007, the entire contents of which are incorporated herein by reference.

### BACKGROUND OF THE INVENTION

1. Field of the Invention

The present invention relates to a nonvolatile semiconductor memory and a manufacturing method thereof, and more particularly to a high-breakdown-voltage MIS transistor that is used in a peripheral circuit.

2. Description of the Related Art

In recent years, a flash memory is used as a memory device in various kind of electronic equipment. In the flash memory, miniaturization of memory cells and an element isolating region that electrically isolates the memory cells has been promoted to increase storage capacity.

The element isolating region has a shallow trench isolation (STI) structure, and a silicon oxide, e.g., TEOS or BPSG is buried in an STI trench by using the chemical vapor deposition (CVD) method in the conventional technology. However, when the STI trench becomes very narrow because of miniaturization, a buried material is not sufficiently buried in the STI trench and a burying failure occurs.

To avoid such a burying failure, for example, a polysilazane-based coating-type silicon oxide is buried in the STI trench in the recent technology (see, e.g., JP-A No. 2006-339446 [KOKAI]).

However, in the coating-type silicon oxide film, an organic substance such as carbon (C) contained in a solvent remains in the silicon oxide film. The remaining carbon (C) may be diffused near a boundary between an element isolation insulating film and a channel region of a high-breakdown-voltage peripheral transistor formed in a peripheral circuit region because of a heat treatment in a manufacturing process, and a fixed charge trap may be possibly formed in the boundary region. This fixed charge trap becomes a factor of an inverse narrow channel effect, a drop in threshold voltage of the transistor becomes prominent, and driving characteristics of the transistor are degraded.

To reduce this influence, a size of the high-breakdown-voltage peripheral transistor is increased or use of the coating-type silicon oxide film is avoided in the peripheral circuit region in the conventional technology.

However, increasing the size of the peripheral transistor leads to a rise in a size of a region where the peripheral transistor is provided. Further, when avoiding use of the coating-type silicon oxide film in the peripheral circuit region, a memory cell region and an element isolation insulting film of the peripheral circuit region must be separately formed, or the coating-type silicon oxide film once formed in the peripheral circuit region must be removed and TEOS and others must be again buried, whereby manufacturing steps are increased.

It is to be noted that JP-A No. 10-65153 (KOKAI) discloses one of the technologies that suppress the inverse narrow channel effect.

Moreover, JP-A No. 10-242294 (KOKAI) discloses a technology of providing an impurity layer that functions as a channel stopper along a bottom surface of an element isolation film.

Additionally, JP-A No. 2002-299475 (KOKAI) discloses a technology of implanting ions into a channel region of a transistor to control a channel concentration.

### BRIEF SUMMARY OF THE INVENTION

A nonvolatile semiconductor memory of an aspect of the present invention comprises: a first element isolation insulating film containing an organic substance which surrounds a first region; a memory cell arranged in the first region; a second element isolation insulating film containing an organic substrate which surrounds a second region; a peripheral transistor arranged in the second region; and a first impurity layer which is provided in the semiconductor substrate along a side surface of the second element isolation insulating film.

A method of manufacturing a nonvolatile semiconductor memory of an aspect of the present invention comprises: forming an element isolation trench in a semiconductor substrate to form an element forming region surrounded by the element isolation trench; forming an impurity layer in the semiconductor substrate along a side surface of the element isolation trench; forming an element isolation insulating film containing an organic substrate in the element isolation trench; and forming a peripheral transistor in the element forming region.

A method of manufacturing a nonvolatile semiconductor memory of an aspect of the present invention comprises: forming a first gate electrode material on a gate insulating film on a semiconductor substrate surface; forming a mask film on the first gate electrode material and patterning the mask film; etching the first gate electrode material and the semiconductor substrate while using the patterned mask film as a mask, and forming an element isolation trench in the semiconductor substrate to form an element forming region surrounded by the element isolation trench; forming an element isolation insulating film containing an organic substance in the element isolation insulating trench; forming an inter-gate insulating film on the first gate electrode material; forming an opening portion at a position of the inter-gate insulating film which is adjacent to the element isolation insulating film; etching the first gate electrode material through the opening portion to expose the gate insulating film; forming an impurity layer in the semiconductor substrate along a side surface of the element isolation insulating trench in a self-aligning manner with respect to the opening portion; forming a second gate electrode material on the gate insulating film exposed through the opening portion and the inter-gate insulating film to connect the second gate electrode material with the first gate electrode material; performing gate processing with respect to the first and second gate electrodes; and forming first and second diffusion layers in the element forming region.

A method of manufacturing a nonvolatile semiconductor memory having a high-breakdown-voltage transistor of an aspect of the present invention comprises: forming a first gate electrode material on a gate insulating film on a semiconductor substrate surface; forming a mask film on the first gage electrode material and patterning the mask film; etching the first gate electrode material and the semiconductor substrate while using the patterned mask film as a mask to form an element isolation trench in the semiconductor substrate, thereby forming an element forming region surrounded by the element isolation trench; removing the mask film at a portion in the element forming region corresponding to a channel region of the high-breakdown-voltage transistor; forming an impurity layer in the semiconductor substrate along the channel region of the high-breakdown-voltage transistor and a side surface of the element isolation trench while using as a mask the mask film removed at the portion corresponding to the channel region; and forming an element isolation insulating film containing an organic substance in the element isolation trench.

### BRIEF DESCRIPTION OF THE SEVERAL VIEWS OF THE DRAWING

FIG. 1 is a schematic view showing an entire structure of a flash memory;

FIG. 2 is a plan view showing a basic structure of a first embodiment;

FIG. 3 is a cross-sectional view taken along line III-III in FIG. 2;

FIG. 4 is a cross-sectional view taken along line IV-IV in FIG. 2;

FIG. 5 is a plan view showing a structure of a memory cell region;

FIG. 6 is a cross-sectional view taken along line VI-VI in FIG. 5;

FIG. 7 is a cross-sectional view taken along line VII-VII in FIG. 5;

FIG. 8 is a plan view showing a structure of a peripheral transistor region;

FIG. 9 is a cross-sectional view taken along line IX-IX in FIG. 8;

FIG. 10 is a cross-sectional view taken along line X-X in FIG. 8;

FIG. 11 is a cross-sectional view showing one step in a manufacturing process according to a first example;

FIG. 12 is a cross-sectional view showing one step in the manufacturing process according to the first example;

FIG. 13 is a cross-sectional view showing one step in the manufacturing process according to the first example;

FIG. 14 is a cross-sectional view showing one step in the manufacturing process according to the first example;

FIG. 15 is a cross-sectional view showing one step in the manufacturing process according to the first example;

FIG. 16 is a cross-sectional view showing one step in the manufacturing process according to the first example;

FIG. 17 is a cross-sectional view showing one step in the manufacturing process according to the first example;

FIG. 18 is a cross-sectional view showing one step in the manufacturing process according to the first example;

FIG. 19 is a cross-sectional view showing one step in the manufacturing process according to the first example;

FIG. 20 is a cross-sectional view showing one step in the manufacturing process according to the first example;

FIG. 21 is a cross-sectional view showing one step in the manufacturing process according to the first example;

FIG. 22 is a cross-sectional view showing one step in the manufacturing process according to the first example;

FIG. 23 is a cross-sectional view showing one step in the manufacturing process according to the first example;

FIG. 24 is a cross-sectional view showing one step in the manufacturing process according to the first example;

FIG. 25 is a cross-sectional view showing one step in the manufacturing process according to the first example;

FIG. 26 is a cross-sectional view showing one step in the manufacturing process according to the first example;

FIG. 27 is a cross-sectional view showing one step in the manufacturing process according to the first example;

FIG. 28 is a cross-sectional view showing one step in the manufacturing process according to the first example;

FIG. 29 is a cross-sectional view showing one step in the manufacturing process according to the first example;

FIG. 30 is a cross-sectional view showing one step in the manufacturing process according to the first example;

FIG. 31 is a cross-sectional view showing structure according to a second example;

FIG. 32 is a cross-sectional view showing structure according to the second example;

FIG. 33 is a cross-sectional view showing structure according to the second example;

FIG. 34 is a cross-sectional view showing structure according to the second example;

FIG. 35 is a cross-sectional view showing one step in a manufacturing process according to a third example;

FIG. 36 is a cross-sectional view showing one step in the manufacturing process according to the third example;

FIG. 37 is a cross-sectional view showing one step in the manufacturing process according to the third example;

FIG. 38 is a cross-sectional view showing one step in the manufacturing process according to the third example;

FIG. 39 is a cross-sectional view showing one step in the manufacturing process according to the third example;

FIG. 40 is a cross-sectional view showing one step in the manufacturing process according to the third example;

FIG. 41 is a plan view showing a basic structure of a second embodiment;

FIG. 42 is a cross-sectional view taken along line XLII-XLII in FIG. 41;

FIG. 43 is a cross-sectional view taken along line XLIII-XLIII in FIG. 41;

FIG. 44 is a plan view showing a structure according to an example according to the second embodiment;

FIG. 45 is a cross-sectional view taken along line XLV-XLV in FIG. 44;

FIG. 46 is a cross-sectional view taken along line XLVI-XLVI in FIG. 44;

FIG. 47 is a plan view showing one step in a manufacturing process according to the example of the second embodiment;

FIG. 48 is a cross-sectional view showing one step in the manufacturing process according to the example of the second embodiment;

FIG. 49 is a cross-sectional view showing one step in the manufacturing process according to the example of the second embodiment;

FIG. 50 is a cross-sectional view showing one conformation of the structure according to the example of the second embodiment;

FIG. 51 is a cross-sectional view showing one conformation of the structure according to the example of the second embodiment;

FIG. 52 is a plan view showing one step in the manufacturing process according to the example of the second embodiment;

FIG. 53 is a plan view showing a basic structure of a third embodiment;

FIG. 54 is a cross-sectional view taken along line LIV-LIV in FIG. 53;

FIG. 55 is a cross-sectional view taken along line LV-LV in FIG. 53;

FIG. 56 is a cross-sectional view showing a structure according to an example of the third embodiment;

FIG. 57 is a cross-sectional view showing the structure according to the example of the third embodiment;

FIG. 58 is a plan view showing one step in a manufacturing process according to the example of the third embodiment;

FIG. 59 is a cross-sectional view showing one step in the manufacturing process according to the example of the third embodiment;

FIG. 60 is a cross-sectional view showing one step in the manufacturing process according to the example of the third embodiment;

FIG. 61 is a plan view showing one step in the manufacturing process according to the example of the third embodiment;

FIG. 62 is a plan view showing a structure according to an example of a fourth embodiment;

FIG. 63 is a cross-sectional view taken along line LXIII-LXIII in FIG. 62;

FIG. 64 is a cross-sectional view taken along line LXIV-IV in FIG. 62;

FIG. 65 is a cross-sectional view showing one step in a manufacturing process according to the fourth embodiment; and

FIG. 66 is a cross-sectional view showing one step in the manufacturing process according to the fourth embodiment.

### DETAILED DESCRIPTION OF THE INVENTION

### 1. Embodiments

### (1) First Embodiment

(A) BASIC STRUCTURE

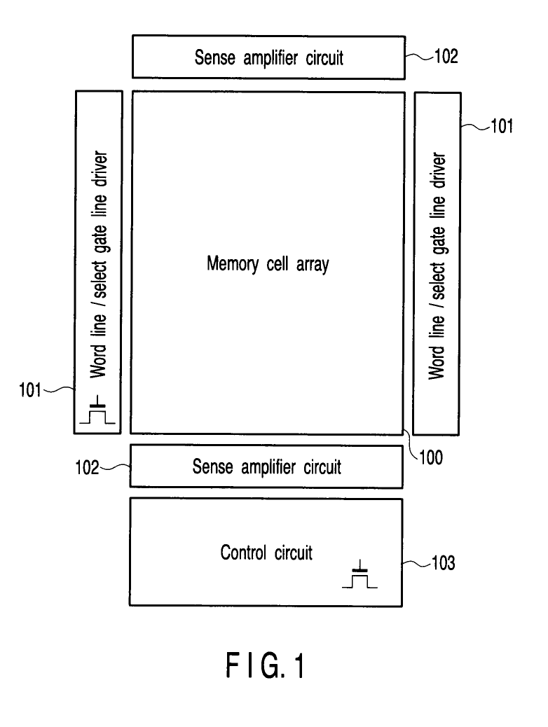

FIG. 1 shows an example of an entire structure of a nonvolatile memory, e.g., a flash memory according to an embodiment of the present invention.

The flash memory is constituted of a memory cell array 100 and a peripheral circuit region arranged around the memory cell array 100. As circuits provided in the peripheral circuit region, there are, e.g., a word line/select gate line driver 101, a sense amplifier circuit 102, and a control circuit 103, and others.

The memory cell array 100 is formed of a plurality of memory cell regions, and a plurality of memory cells are provided on one memory cell region. A plurality of high-breakdown-voltage or low-breakdown-voltage MIS (Metal-Insulator-Semiconductor) transistors are provided in peripheral circuits 101, 102, and 103.

A first embodiment according to the present invention is characterized in that an impurity layer is provided in a semiconductor substrate 1 along a side surface of an element isolation insulating film that surrounds a region where the high-breakdown-voltage MIS transistor used in a peripheral circuit is formed.

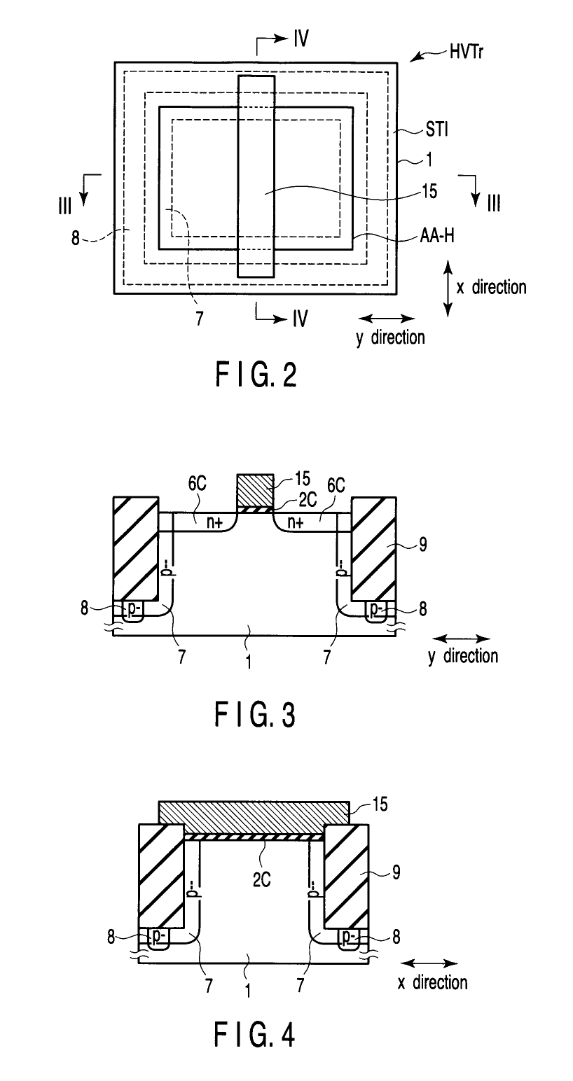

A basic structure of a high-breakdown-voltage MIS transistor HVTr according to this embodiment will now be explained with reference to FIGS. 2 to 4. FIG. 2 shows a planar structure of the high-breakdown-voltage MIS transistor. Further, FIG. 3 shows a cross-sectional structure taken along line III-III in FIG. 2, and FIG. 4 shows a cross-sectional structure taken along line IV-IV in FIG. 2.

An n-channel high-breakdown-voltage MIS transistor HVTr shown in FIGS. 2 to 4 is provided in an element forming region (active region, second region) AA-H surrounded by an element isolating region STI. The active region AA-H is formed in a peripheral circuit region of a first conductivity type (e.g., a p-type) semiconductor substrate (e.g., a silicon substrate). This active region AA-H is a region where a well region is not provided and an impurity concentration is low (which will be referred to as an intrinsic region hereinafter).

Two diffusion layers 6C having a second conductivity type (n-type in this example) that is opposite to the first conductivity type are provided in the active region AA-H. The two diffusion layers 6C function as a source and a drain of the high-breakdown-voltage MIS transistor HVTr. The diffusion layers that become the source and the drain will be referred to as source/drain diffusion layers hereinafter.

A gate electrode 15 of the high-breakdown-voltage MIS transistor HVTr is provided on the semiconductor substrate (channel region surface) between the two diffusion layers 6C through a gate insulating film 2C (e.g., a silicon oxide film). It is to be noted that the gate insulating film may be a high-dielectric insulating film formed of, e.g., HfSiON or Al₂O₃.

An element isolation insulating film 9 having an STI structure is buried in the element isolating region STI. This element isolation insulating film 9 is an insulating film formed of, e.g., a polysilazane-based coating-type silicon oxide film, and contains an organic substance, e.g., carbon (C).

A p-type second impurity layer 8 is provided in the semiconductor substrate 1 along a bottom surface of this element isolation insulating film 9 to surround the active region AA-H. This impurity layer 8 functions as a channel stopper between elements adjacent to each other.

Further, in this embodiment, a first-conductivity-type (p-type) first impurity layer 7 is provided in the semiconductor substrate 1 along a side surface and the bottom surface of the element isolation insulating film 9 to further surround the active region AA-H. An impurity concentration of this first impurity layer 7 is lower than an impurity concentration of the second impurity layer 8.

When the element isolation insulating film 9 is formed of an insulating film containing an organic substance, this organic substance is diffused into the semiconductor substrate 1 and a fixed charge trap is thereby formed along the element isolation insulating film 9.

As explained above, the high-breakdown-voltage MIS transistor HVTr is provided in the intrinsic region having a low impurity concentration. Therefore, in the high-breakdown-voltage MIS transistor, an influence of the fixed charge trap on operation characteristics is large and becomes a factor of the inverse narrow channel effect, especially when the fixed charge trap is formed in the channel region.

However, according to this embodiment, providing the impurity layer 7 along the side surface of the element isolation insulating film 9 enables alleviating the influence of the fixed charge trap caused by the organic substance, thereby suppressing the inverse narrow channel effect of a peripheral transistor used in a nonvolatile semiconductor memory, e.g., an n-channel high-breakdown-voltage MIS transistor provided in an intrinsic region.

Several examples based on the fundamental structure shown in FIGS. 2 to 4 will now be explained hereinafter.

### (B) EXAMPLES

### (i) First Example

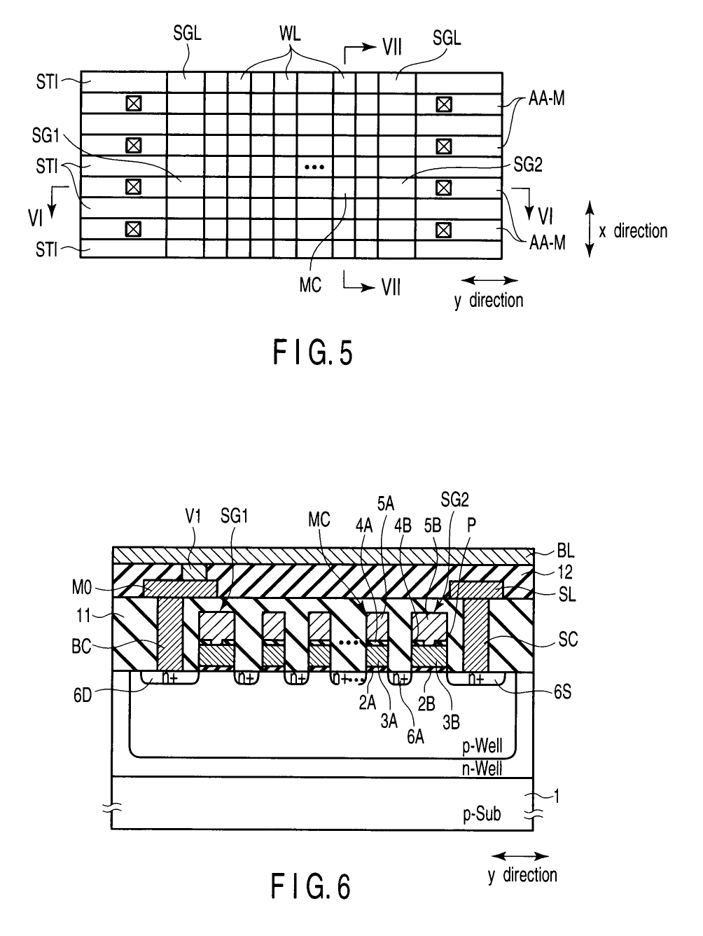

A first example of this embodiment will now be explained with reference to FIGS. 5 to 30.

(a) Structure

A structure of each element constituting a memory cell region and a peripheral circuit region according to this example will now be described with reference to FIGS. 5 to 10.

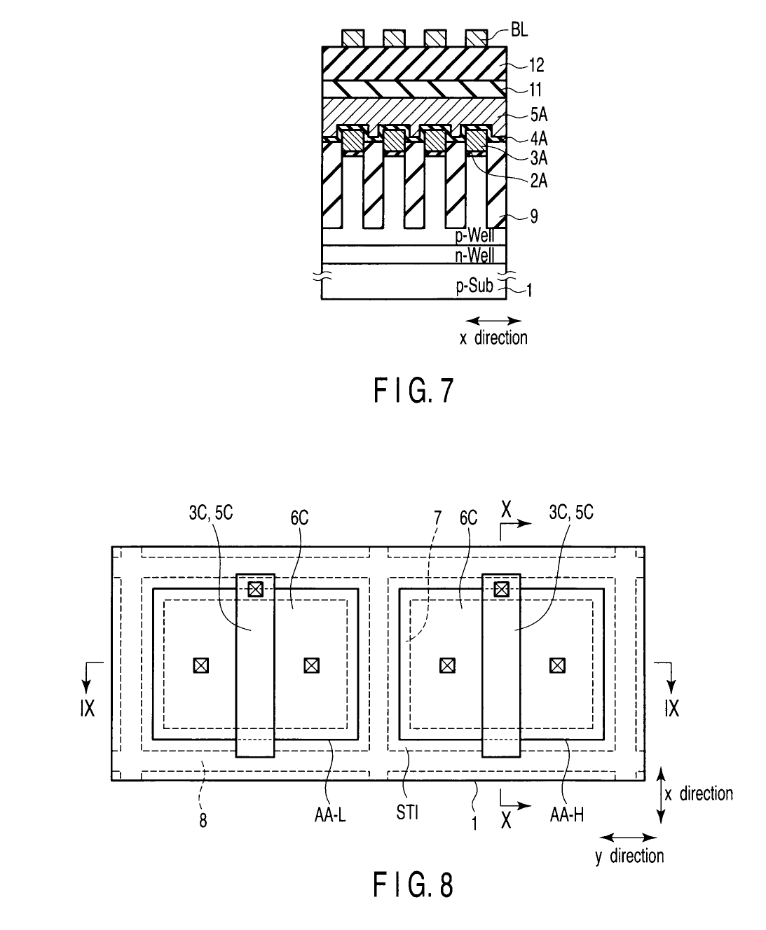

FIG. 5 is a plan view of a memory cell region in which a plurality of memory cells are provided. FIG. 6 is a cross sectional view taken along line VI-VI in FIG. 5, and FIG. 7 is a cross-sectional view taken along line VII-VII in FIG. 5. It is to be noted that the memory cell region will be explained while taking a structure of a NAND flash memory as an example in this embodiment, but the present invention is not restricted thereto, and any other structure of, e.g., a NOR flash memory can be adopted.

As shown in FIGS. 5 to 7, in a memory cell region, a well region having a so-called double well structure including an n-type N well region N-well and a p-type P well region P-well formed in the N well region N-well is provided in a p-type semiconductor substrate 1. Further, a plurality of memory cells MC and select gate transistors SG1 and SG2 are provided in the P well region P-Well.

A surface region of the semiconductor substrate 1 in the P well region P-Well is formed of an element isolating region STI and an active region AA-M (first region) surrounded by the element isolating region STI.

The memory cell MC is an MIS transistor having a stacked gate structure formed of a floating gate electrode 3A and a control gate electrode 5A. The floating gate electrode 3A is provided on a gate insulating film 2A laminated on a surface of the active region AA-M. This floating gate electrode 3A functions as a charge storage layer. The control gate electrode SA is formed on the floating gate electrode 3A through an inter-gate insulating film 4A. The control gate electrode 5A functions as a word line WL, and the control gate electrodes 5A are connected in the plurality of memory cells MC adjacent to each other in a channel width direction (the x-direction) of the memory cells MC in common.

Moreover, in the memory cell region, an upper end of an element isolation insulating film (first element isolation insulating film) 9 is lower than an upper end of the floating gate electrode 3A and higher than a surface of the semiconductor substrate 1. With the structure of this element isolation insulating film 9, the control gate electrode 5A covers a side surface of the floating gate electrode 3A in the channel width direction (the x-direction) through the inter-gate insulating film 4A. The plurality of memory cells MC adjacent to each other share n-type source/drain diffusion layers 6A and are connected in series along a channel length direction (the y-direction) of the memory cells MC.

The select gate transistors SG1 and SG2 are provided at both ends of the plurality of memory cells MC. The select gate transistors SG1 and SG2 are formed concurrently with the memory cells MC. Therefore, each of the select gate transistors SG1 and SG2 becomes an MIS transistor having a stacked gate structure like the memory cells MC. In each of the select gate transistors SG1 and SG2, a first gate electrode 3B and a second gate electrode 5B provided on a gate insulating film 2B are connected with each other through an opening portion P formed in an inter-gate insulating film 4B interposed between the first gate electrode 3B and the second gate electrode 5B. The first and second gate electrodes 3B and 5B function as a select gate line SGL. It is to be noted that the first gate electrode 3B is formed concurrently with the floating gate electrode 3A, and the second gate electrode 5B is formed simultaneously with the control gate electrode 5A.

Each of the select gate transistors SG1 and SG2 is connected in series with the memory cell MC adjacent thereto through the n-type diffusion layer 6A. A bit line BL is connected with an n-type drain diffusion layer 6D of the select gate transistor SG1 arranged on a drain side of the plurality of memory cells MC through a bit line contract BC, an intermediate metal layer M0, and a via plug V1 buried in interlayer insulating films 11 and 12. Furthermore, a source line SL is connected with an n-type source diffusion layer 6S of the select gate transistor SG2 arranged on a source side of the plurality of memory cells MC through a source line contact SC buried in the interlayer insulating film 11.

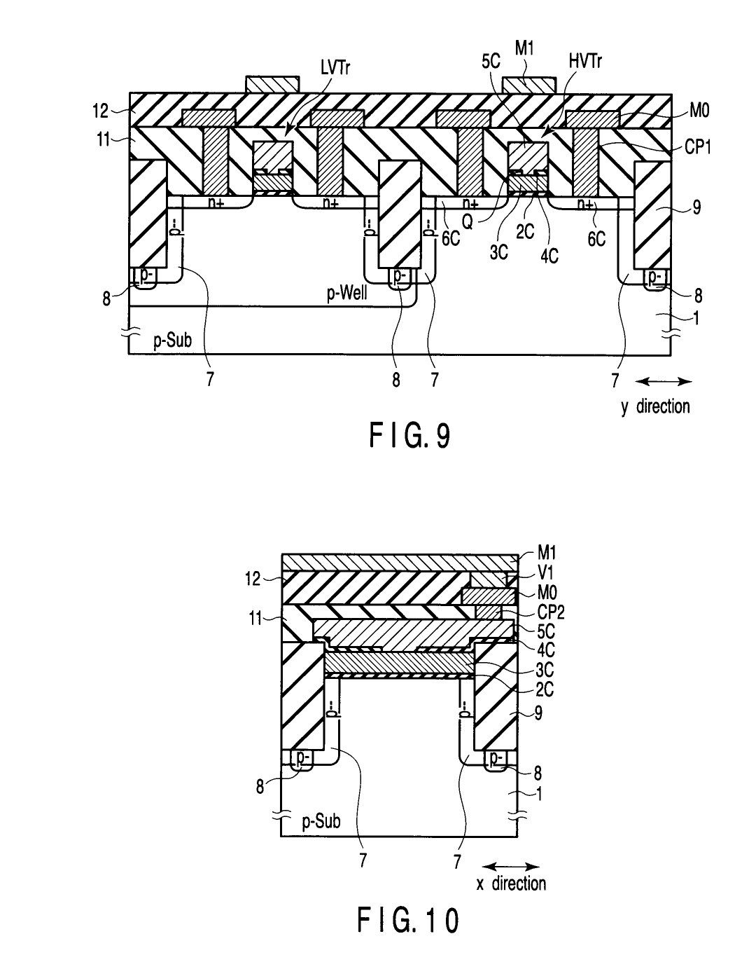

A structure of the peripheral transistor region in which a plurality of peripheral transistors are provided will now be explained. FIG. 8 is a plan view showing a structure of peripheral transistors provided in the peripheral transistor region. FIG. 9 is a cross-sectional view taken along line IX-IX in FIG. 8, and FIG. 10 is a cross-sectional view taken along line X-X in FIG. 8. It is to be noted that each of FIGS. 8 to 10 shows one low-breakdown-voltage transistor LVTr and one high-breakdown-voltage transistor HVTr.

In the peripheral transistor region in a peripheral circuit region of the semiconductor substrate 1, an active region (third region) AA-L in which the P well region P-Well is surrounded by the element isolating region STI and an active region (a second region) AA-H in which a region where the well region is not provided (an intrinsic region) is surrounded by the element isolating region STI are formed. An n-channel low-breakdown-voltage MIS transistor LVTr is provided in this active region AA-L, and an n-channel high-breakdown-voltage MIS transistor HVTr is provided in the active region AA-H. In the following explanation, a region where the low-breakdown-voltage MIS transistor LVTr is provided in the peripheral transistor region will be referred to as a low-breakdown-voltage MIS transistor region. Furthermore, a region where the high-breakdown-voltage MIS transistor HVTr is provided in the peripheral transistor region will be referred to as a high-breakdown-voltage MIS transistor region.

Since the active region AA-H is the intrinsic region, the high-breakdown-voltage MIS transistor has a lower substrate bias effect than does the low-breakdown-voltage MIS transistor.

Like the select gate transistors SG1 and SG2, the low-breakdown-voltage MIS transistor LVTr and the high-breakdown-voltage MIS transistor HVTr are formed concurrently with the memory cells MC. Therefore, a first gate electrode 3C and a second gate electrode 5C on a gate insulating film 2C formed on the surface of the semiconductor substrate 1 are laminated. An inter-gate insulating film 4C is interposed between the first gate electrode 3C and the second gate electrode 5C. An opening portion Q is formed in this inter-gate insulating film 4C, and the first gate electrode 3C and the second gate electrode 5C are connected with each other through this opening portion Q. It is to be noted that a gate length of each of the low-breakdown-voltage and high-breakdown-voltage MIS transistors LVTr and HVTr is longer than a gate length of the memory cell MC.

Intermediate metal layers M0 are connected with n-type diffusion layers 6C that become a source and a drain of the MIS transistor LVTr or HVTr through contact plugs CP1. Additionally, a metal layer M1 as a gate interconnect line is connected with the second gate electrode 5C of the MIS transistor LVTr or HVTr through a contact plug CP2, the intermediate metal layer M0, and a via contact V1.

Here, the element isolating region STI of each of the memory cell region and the peripheral transistor region has a structure where the element isolation insulating film (the first or second element isolation insulating film) 9 is buried in the element isolation trench having the STI structure, for example. It is to be noted that a size of the element isolation trench in the peripheral transistor region is larger than a size of the element isolation trench in the memory cell region. Therefore, a size of the element isolation insulating film in the peripheral transistor region is larger than a size of the element isolation insulting film in the memory cell region.

The element isolation insulating film 9 is formed of a polysilazane-based silicon oxide film. This polysilazane-based silicon oxide film contains an organic substance such as carbon (C).

In this embodiment, a second impurity layer 8 is provided along a bottom surface of the element isolation insulating film 9 in the peripheral transistor region to surround the active region AA-L or AA-H of each MIS transistor LVTr or HVTr. This second impurity layer 8 functions as a channel stopper. Further, a first impurity layer 7 is provided in the semiconductor substrate 1 along a side surface and the bottom surface of the element isolation insulating film 9 to surround the active region AA-H of the high-breakdown-voltage MIS transistor HVTr.

The first and second impurity layers 7 and 8 are p-type impurity layers and formed in such a manner that an impurity concentration of the first impurity layer 7 becomes lower than an impurity concentration of the second impurity layer 8. For example, the impurity concentration of the first impurity layer 7 is approximately 10¹⁵/cm³, and the impurity concentration of the second impurity layer 8 is approximately 10¹⁶/cm³.

The element isolation insulating film 9 is formed by applying a coating liquid to the inside of the semiconductor substrate 1 based on spin coating and performing a heat treatment with respect to the coating liquid in an oxygen atmosphere to convert the coating liquid into a silicon oxide film. This heat treatment is carried out while reducing a heat treatment temperature to suppress oxidation of polysilicon forming a gate insulating film and a gate electrode. Therefore, the heat treatment of the coating liquid becomes insufficient, the organic substance in the element isolation insulating film material is diffused into the semiconductor substrate 1, and a fixed charge trap is formed on an interface between the semiconductor substrate 1 and the element isolation insulating film 9.

According to this embodiment, providing the first impurity layer 7 along the side surface of the element isolation insulating film 9 enables alleviating an influence of the fixed charge trap caused by the organic substance when the element isolation insulating film 9 is formed of an insulator containing the organic substance.

Furthermore, when the impurity layer 7 is provided, a substrate impurity concentration in the active region AA-H where the high-breakdown-voltage MIS transistor HVTr is provided is increased. As a result, the substrate bias effect determined based on the substrate impurity concentration can be improved in the high-breakdown-voltage MIS transistor.

In general, when an impurity concentration in an impurity layer is increased, a junction leak between the impurity layer and a semiconductor substrate is increased. However, in this embodiment, setting the impurity concentration in the first impurity layer 7 to an impurity concentration (approximately 10¹⁵/cm³) that can suppress the fixed charge trap can suffice, and the first impurity layer 7 does not have to be formed with a high impurity concentration that notably produces the junction leak.

Therefore, according to this embodiment, it is possible to suppress degradation of driving characteristics of the peripheral transistor caused by to the fixed charge trap, especially the inverse narrow channel effect of the high-breakdown-voltage MIS transistor provided in the intrinsic region.

(b) Manufacturing Method.

A manufacturing method of a flash memory according to this embodiment will now be explained with reference to FIGS. 5 to 30.

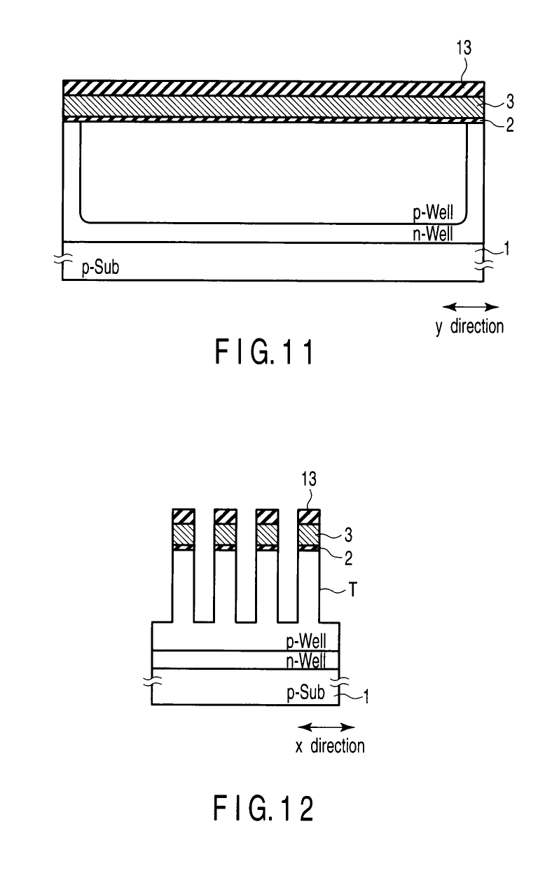

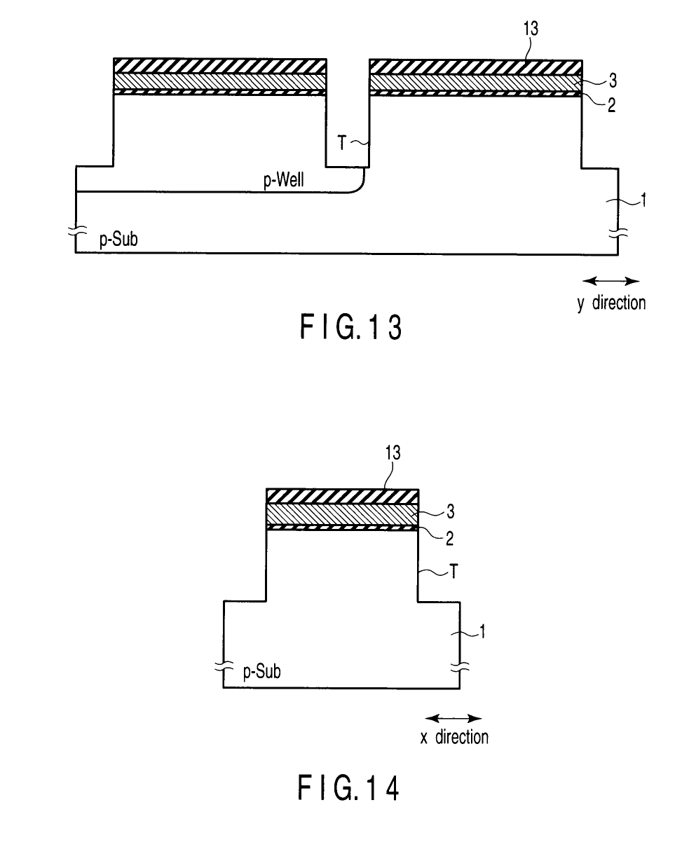

First, a manufacturing process of the memory cell region and the peripheral transistor region will be explained with reference to FIGS. 11 to 14. FIG. 11 is a cross-sectional view along the y-direction (channel length direction) of the memory cell region, and FIG. 12 is a cross-sectional view along the x-direction (channel width direction) of the memory cell region. FIG. 13 is a cross-sectional view along the y-direction (the channel length direction) of the peripheral transistor region, and FIG. 14 is a cross-sectional view along the x-direction (the channel width direction) of the peripheral transistor region.

As shown in FIG. 11, in the memory cell region, based on the thermal oxidation method, the gate insulating film 2 is formed on the surface of the semiconductor substrate 1 having the well regions formed therein. Then, a polysilicon film (first gate electrode material) 3 that becomes a floating gate electrode of a memory cell is formed on the gate insulating film 2. Furthermore, a mask film 13 constituted of a silicon nitride film is formed on the polysilicon film 3 based on, e.g., the CVD method.

Moreover, as shown in FIG. 13, in the peripheral transistor region, the gate insulating film 2, the polysilicon film 3 that becomes the first gate electrode, and the mask film 13 are sequentially formed simultaneously with formation of the films in the memory cell region.

Subsequently, as shown in FIGS. 12 and 14, element isolation trenches T each having an STI structure are formed with predetermined sizes in the semiconductor substrate 1 in the memory cell region and the peripheral transistor region based on the reactive ion etching (RIE) method while using a mask film 13 as a mask. Here, the element isolation trench T isolates the active region AA-H of the high-breakdown-voltage MIS transistor HVTr from the active region AA-L of the low-breakdown-voltage MIS transistor LVTr, and is formed at a boundary portion of the P well region P-Well.

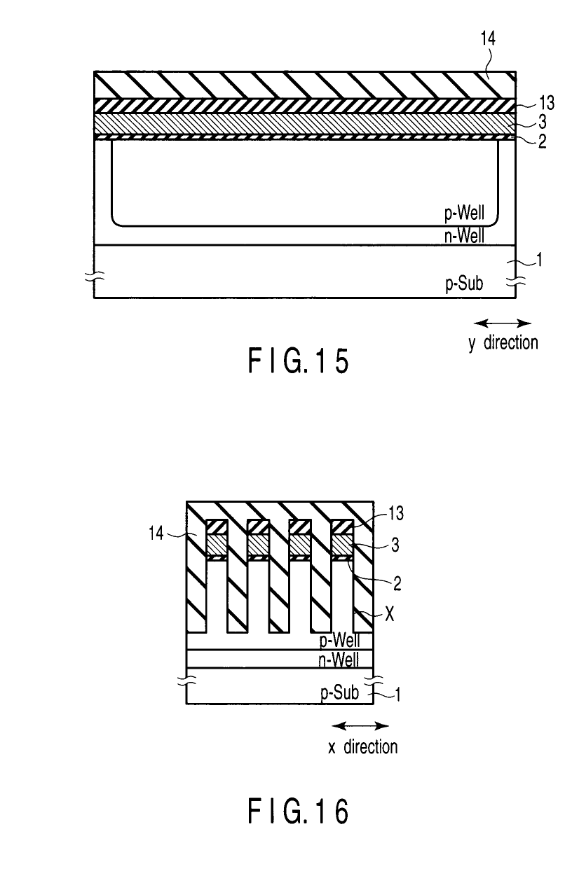

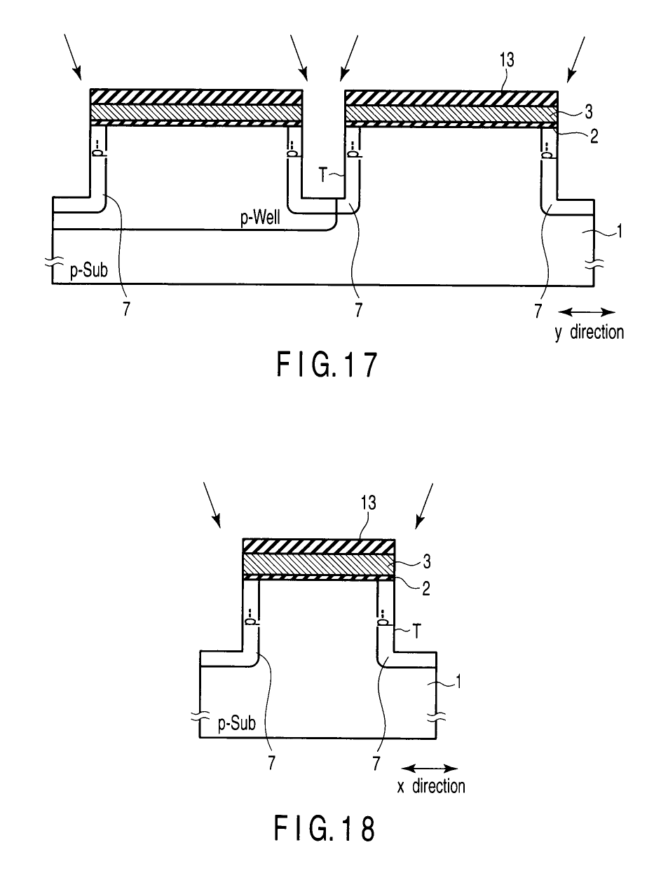

Then, manufacturing steps following FIGS. 11 to 14 will now be explained with reference to FIGS. 15 to 18. FIG. 15 is a cross-sectional view along the y-direction of the memory cell region, and FIG. 16 is a cross-sectional view along the x-direction of the memory cell region. Additionally, FIG. 17 is a cross-sectional view along the y-direction of the peripheral transistor region, and FIG. 18 is a cross-sectional view along the x-direction of the peripheral transistor region.

As shown in FIGS. 15 and 16, a resist mask 14 is formed above the memory cell region.

Then, as shown in FIGS. 17 and 18, a p-type impurity (e.g., boron (B)) is implanted into the semiconductor substrate 1 with respect to the element isolation trench T in a region where the high-breakdown-voltage MIS transistor is planned to be formed based on the ion implantation method in an oblique direction where an incidence angle of the ions is set to a predetermined angle. As a result, the impurity layer 7 is formed along a side surface and a bottom surface of the element isolation trench T. This impurity layer 7 is formed in such a manner that its impurity concentration becomes, e.g., approximately 10¹⁵/cm³.

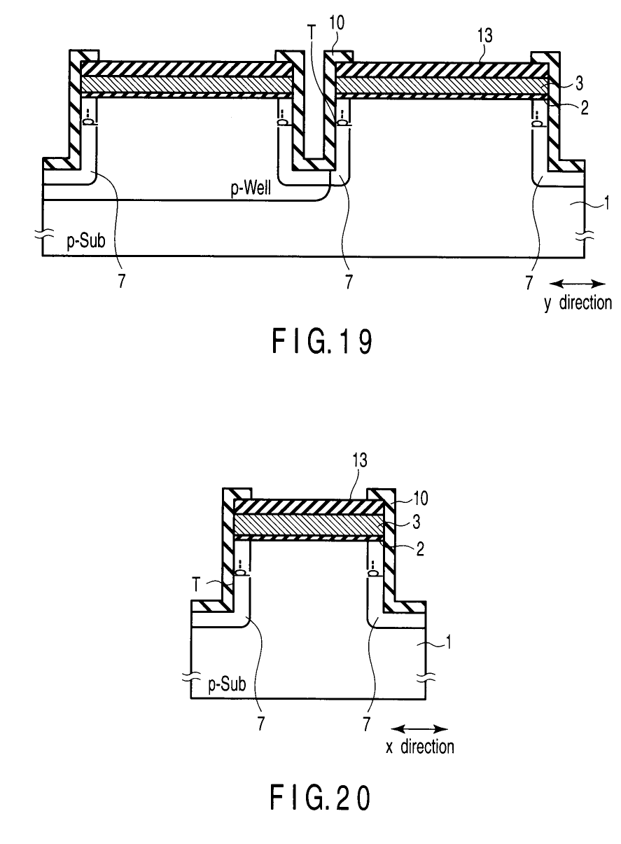

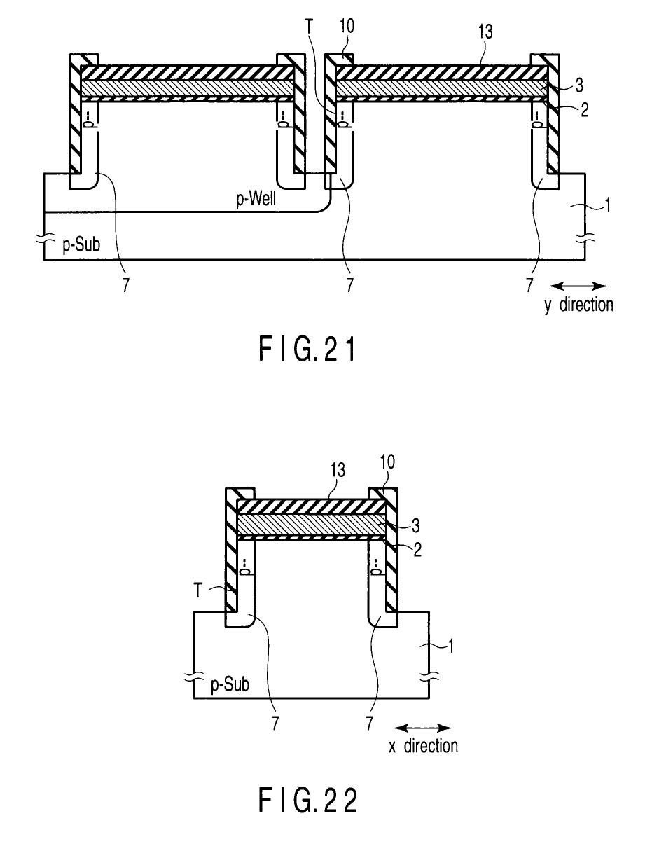

It is to be noted that the impurity layer 7 is not restricted to the above-explained forming method and it can be formed based on the solid-phase diffusion method. For example, as shown in FIGS. 19 and 20, boron silicon glass (BSG) is formed as a solid-phase diffusion source 10 along the side surface and the bottom surface of the element isolation insulating trench T surrounding a periphery of the region where the high-breakdown-voltage MIS transistor is planned to be formed. Thereafter, a heat treatment is performed at a temperature that the BSG is not completely molten, and boron (B) ions contained in the BSG are thermally diffused in the semiconductor substrate 1, thereby forming the impurity layer (the first impurity layer) 7. It is to be noted that the solid-phase diffusion source 10 may be formed on the side surface alone of the element isolation trench T as shown in FIGS. 21 and 22.

In contrast to the ion implantation method, when forming the impurity layer 7 by means of the solid-phase diffusion method, the semiconductor substrate 1 is not damaged by accelerated ions. Therefore, it is possible to suppress degradation of driving characteristics of the peripheral transistor caused by a crystal defect in the semiconductor substrate 1. It is to be noted that this solid-phase diffusion source 10 is removed after the impurity layer 7 is formed.

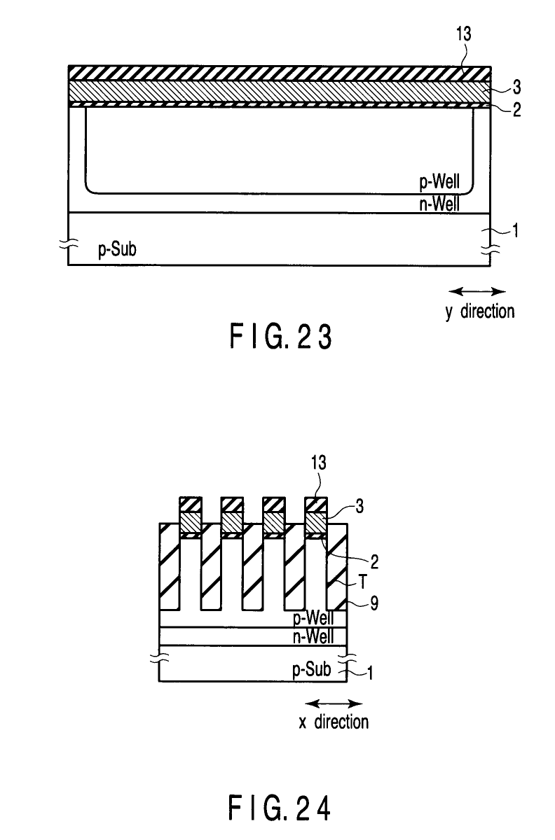

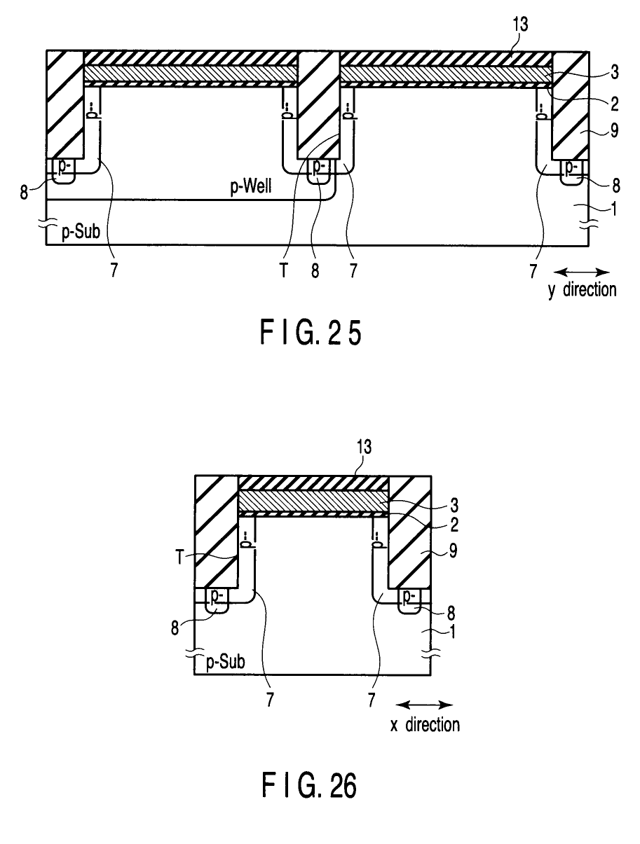

Then, manufacturing steps following the above-described steps will now be explained with reference to FIGS. 23 to 26. FIG. 23 is a cross-sectional view along the y-direction of the memory cell region, and FIG. 24 is a cross-sectional view along the x-direction of the memory cell region. Further, FIG. 25 is a cross-sectional view along the y-direction of the peripheral transistor region, and FIG. 26 is a cross-sectional view along the x-direction of the peripheral transistor region.

After removing the resist mask 14 formed in the memory cell region, polysilazane is buried in each element isolation trench T in the memory cell region and the peripheral transistor region based on a coating method as shown in FIGS. 24 to 26. Subsequently, polysilazane is heated, and the element isolation insulating film 9 is formed in each element isolation trench T.

Then, a resist mask (not shown) is formed in each of the memory cell region and the peripheral transistor region based on a photolithography technology. Furthermore, this is used as a mask, and the impurity layer 8 that functions as a channel stopper is formed in the semiconductor substrate 1 along a bottom surface of the element isolation insulating film 9 in the peripheral transistor region based on the ion implantation method to surround the active region of the peripheral transistor. At this time, the impurity layer 8 is formed in such a manner that its impurity concentration becomes, e.g., approximately 10¹⁶/cm³.

In the memory cell region, after removing the resist mask, as shown in FIG. 24, the element isolation insulating film 9 is etched back based on the RIE method to recede toward the semiconductor substrate 1 side. As a result, a side surface in the channel width direction of the polysilicon film 3 that becomes the floating gate electrode is exposed.

At this time, the element isolation insulating film 9 is not etched back while covering the peripheral transistor region with a resist mask (not shown). Therefore, in the peripheral transistor region, an upper end of the element isolation insulating film 9 is higher than an upper end of the polysilicon film 3 that becomes the first gate electrode. It is to be noted that the element isolation insulating film 9 has a structure where its upper end is placed to be higher than the surface of the semiconductor substrate 1.

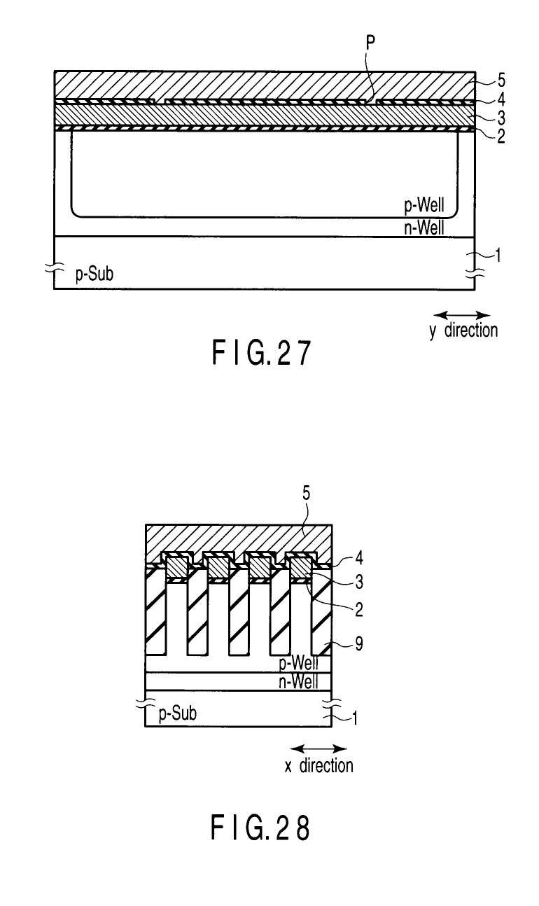

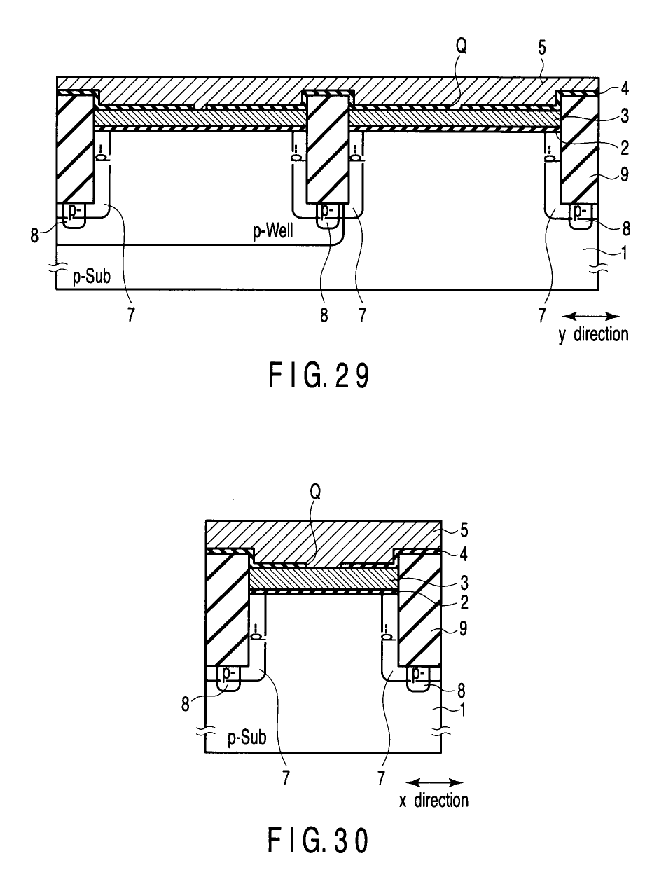

Manufacturing steps following the steps depicted in FIGS. 23 to 26 will now be explained with reference to FIGS. 27 to 30. FIG. 27 is a cross-sectional view along the y-direction of the memory cell region, and FIG. 28 is a cross-sectional view along the x-direction of the memory cell region. Moreover, FIG. 29 is a cross-sectional view along the y direction of the peripheral transistor region, and FIG. 30 is a cross-sectional view along the x direction of the peripheral transistor region.

As shown in FIGS. 27 to 30, after removing the resist mask and the mask film, the inter-gate insulating film 4 is deposited on the polysilicon film 3 based on the CVD method. The inter-gate insulating film 4 is formed of, e.g., a single-layer film or a laminated film of a silicon oxide film, a silicon nitride film, or a high-dielectric film containing HfSiON or Al₂O₃. Additionally, the opening portions P and Q are formed in the inter-gate insulating films 4 in a region where the select gate transistor is planned to be formed and regions where the low-breakdown-voltage and high-breakdown-voltage MIS transistors are planned to be formed, respectively. Then, a polysilicon film (second gate electrode material) 5 that becomes a control gate electrode or a second gate electrode is deposited on the inter-gate insulating film 4 based on the CVD method.

Subsequently, as shown in FIGS. 5 to 10, gate processing is executed in the memory cell region and the peripheral transistor region based on the RIE method in such a manner that each of the memory cells, the select gate transistors, and the peripheral transistors has a predetermined gate length. As a result, stacked gate electrodes of the memory cells MC, the select gate transistors SG1 and SG2, the low-breakdown-voltage and the high-breakdown-voltage MIS transistors are formed, respectively.

Then, the source/drain diffusion layers 6A, 6D, 6S and 6C are formed in the semiconductor substrate 1 in a self-aligning manner with respect to the stacked gate electrodes based on the ion implantation method.

Subsequently, the first interlayer insulating film 11 is formed based on the CVD method. Moreover, the source lines SL and the intermediate metal layers M0 are connected with the source/drain diffusion layers 6D, 6S, and 6C through the bit line and source line contacts BC and SC and the contact plugs CP1 buried in the first interlayer insulating film 11, respectively.

Additionally, a second interlayer insulating layer 12 is formed on the first interlayer insulating layer 11. Further, in the memory cell region, the bit line BL is connected with the intermediate metal layer M0 through the via contact V1. At the same time, in the peripheral transistor region, a gate line M1 is connected with the contact plug CP2 and the intermediate metal layer M0 through the via contact V1, thereby connecting the gate line M1 with the gate electrodes 3C and 5C.

With the above-explained steps, the memory cells and the peripheral transistors according to this example are formed.

According to the manufacturing method of this embodiment, the first impurity layer 7 can be formed in the semiconductor substrate 1 along the side surface of the element isolation insulating film 9 in the high-breakdown-voltage MIS transistor region (the active region AA-H). Therefore, even when the organic substance contained in the element isolation insulating film 9 is diffused into the semiconductor substrate 1 to form the fixed charge trap, the impurity layer 7 formed along the side surface of the element isolation insulating film 9 can alleviate the influence of the fixed charge trap.

Accordingly, it is possible to provide the nonvolatile semiconductor memory in which degradation of driving characteristics of each peripheral transistor caused by the fixed charge trap, especially the inverse narrow channel effect of the high-breakdown-voltage MIS transistor, is suppressed.

### (ii) Second Example

A second example of this embodiment will now be explained with reference to FIGS. 31 to 34. It is to be noted that like reference numbers denote members equal to those in the first example, thereby omitting a detailed explanation. Further, since a structure of a memory cell region is equal to that in the first example, thus omitting an explanation thereof.

In the first example, as one of the methods of forming an impurity layer on a side surface of an element isolation insulating film, the method of forming the first impurity layer 7 by using the solid-phase diffusion source 10 has been explained as shown in FIGS. 19 to 22. The BSG as the solid-phase diffusion source explained in the first example is an insulating material. Therefore, in the second example, this BSG is used as a part of the element isolation insulating film without being removed.

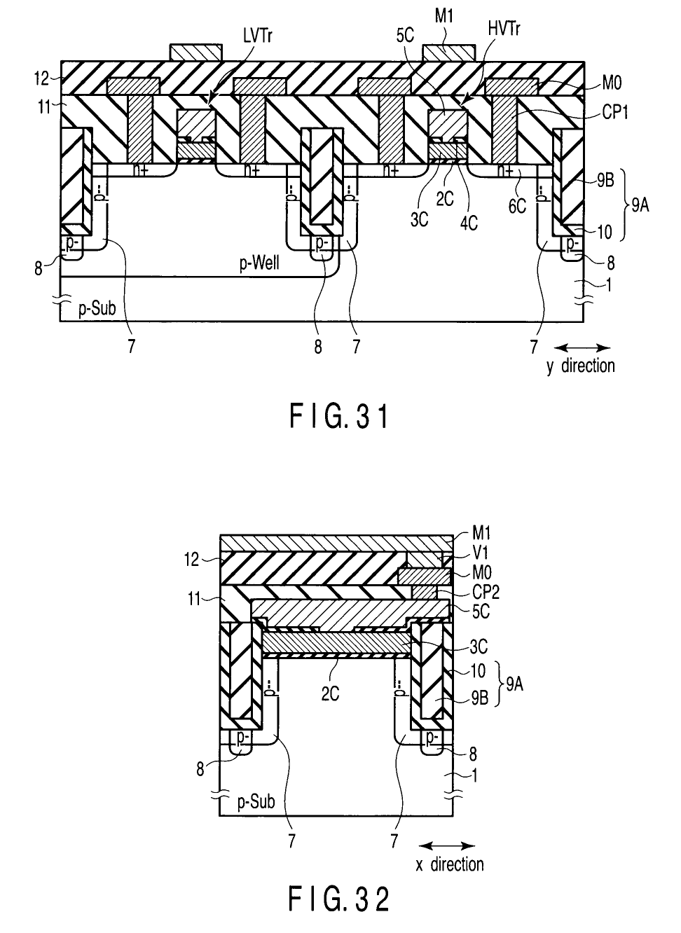

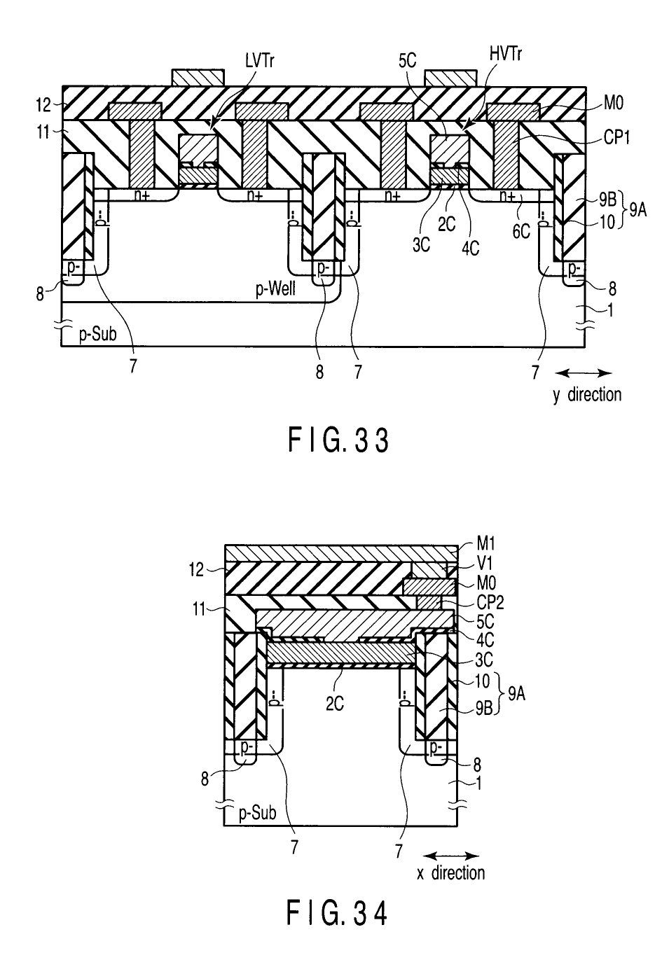

In this case, a structure of a high-breakdown-voltage MIS transistor is a structure shown in FIGS. 31 and 32 or FIGS. 33 and 34. FIGS. 31 and 33 are cross-sectional views along the y-direction of a peripheral transistor region, and FIGS. 32 and 34 are cross-sectional view along the x-direction of the peripheral transistor region.

As shown in FIGS. 31 and 32 or FIGS. 33 and 34, an element isolation insulating film 9A is formed of a first insulating film 9B containing an organic substance and a second insulating film 10 provided between this first insulating film 9B and a semiconductor substrate 1. The second insulating film 10 serves as a solid-phase diffusion source that is used to form a first impurity layer 7. The first insulating film 9B having polysilazane, and the second insulating film 10 consists of, e.g., BSG.

In the example shown in FIGS. 31 and 32, a bottom portion of the second insulating film 10 in the element isolation insulating film 9A is in contact with an impurity layer 8 that functions as a channel stopper. Further, in the example shown in FIGS. 33 and 34, a bottom portion of the first insulating film 9B in the element isolation insulating film 9A is in contact with the impurity layer 8 that functions as the channel stopper.

According to the above-explained structure, the second insulating film 10 interposed between the first insulating film 9B containing the organic substance and the semiconductor substrate 1 forms the first impurity layer 7. Therefore, diffusion of the organic substance contained in the first insulating film 9 into the semiconductor substrate 1 can be reduced, and formation of a fixed charge trap caused by the organic substance can be suppressed in the semiconductor substrate 1.

Furthermore, according to the structure shown in FIGS. 33 and 34, in its manufacturing process, the impurity layer 8 that becomes the channel stopper can be formed in a self-aligning manner while using the second insulating film 10 as a mask. Therefore, the manufacturing process of this embodiment can be simplified.

In this example, likewise, providing the first impurity layer 7 in the semiconductor substrate 1 along the element isolation insulating film 9A enables alleviating an influence of the fixed charge trap caused by the organic impurity.

Therefore, it is possible to suppress degradation of driving characteristics of the peripheral transistor caused by the fixed charge trap, especially an inverse narrow channel effect of a high-breakdown-voltage MIS transistor provided in an intrinsic region.

### (iii) Third Example

In the first and second examples, the description has been given as to the case where the structure according to this embodiment is formed by using the manufacturing method of forming the first gate electrode material that becomes the floating gate electrode of each memory cell and then forming the first impurity layer that alleviates the influence of the fixed charge trap.

However, the manufacturing method of obtaining the structure according to the embodiment of the present invention is not restricted thereto. For example, even when the first impurity layer 7 can be simultaneously formed with the P well in the region where the n-channel low-breakdown-voltage MIS transistor is provided and then the first gate electrode material is formed, a structure similar to that shown in FIGS. 8 to 10 can be fabricated.

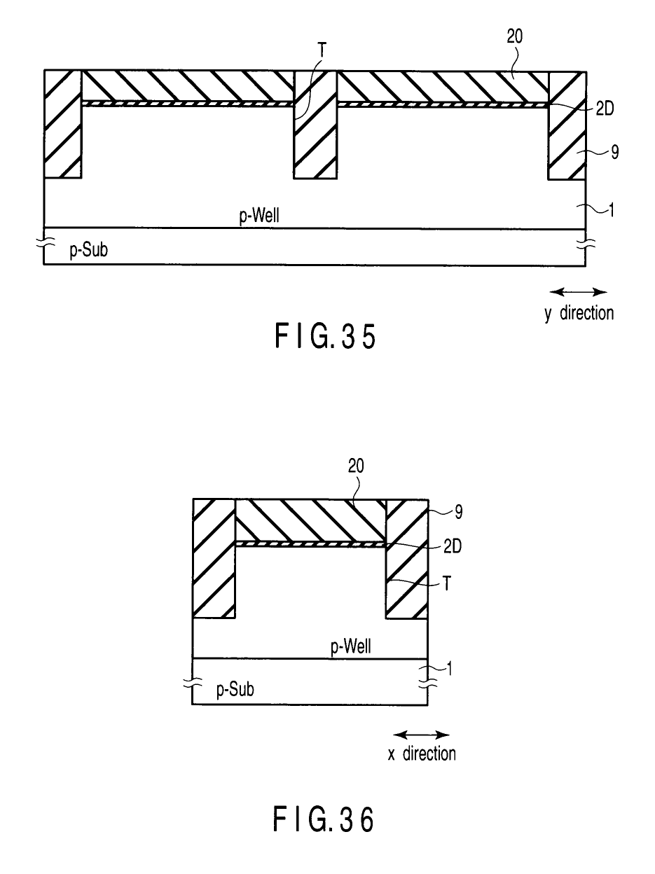

In the third example of this embodiment, this manufacturing method will be explained with reference to FIGS. 35 to 40. It is to be noted that, in this example, like reference numbers denote members equal to those in the first and second examples, thereby omitting a detailed explanation thereof. Furthermore, in this example, a detailed explanation of a memory cell region will be omitted.

One step in this example will be first explained with reference to FIGS. 35 and 36. FIG. 35 is a cross-sectional view along the y-direction of a peripheral transistor region, and FIG. 36 is a cross-sectional view along the x-direction of the peripheral transistor region.

As shown in FIGS. 35 and 36, a dummy oxide film 2D is formed on a surface of a semiconductor substrate 1 in a peripheral transistor region. Then, a dummy layer 20 is formed on the dummy oxide film 2D.

Subsequently, a p-type impurity is implanted into the semiconductor substrate 1 in an active region AA-H of a high-breakdown-voltage MIS transistor and an active region AA-L of a low-breakdown-voltage MIS transistor based on the ion implantation method. As a result, a well region p-Well is formed in the semiconductor substrate 1 in each of the active region AA-H and the active region AA-L. This well region p-Well becomes a P well region for an n-channel low-breakdown-voltage MIS transistor and an impurity layer that suppresses a fixed charge trap at a later step. It is to be noted that a P well region for a memory cell region may be formed simultaneously with formation of the well region p-Well.

Then, each element isolation trench T is formed in the semiconductor substrate 1. Moreover, the element isolation trench T is filled with an insulating material using polysilazane containing an organic substance, thereby forming each element isolation insulating film 9.

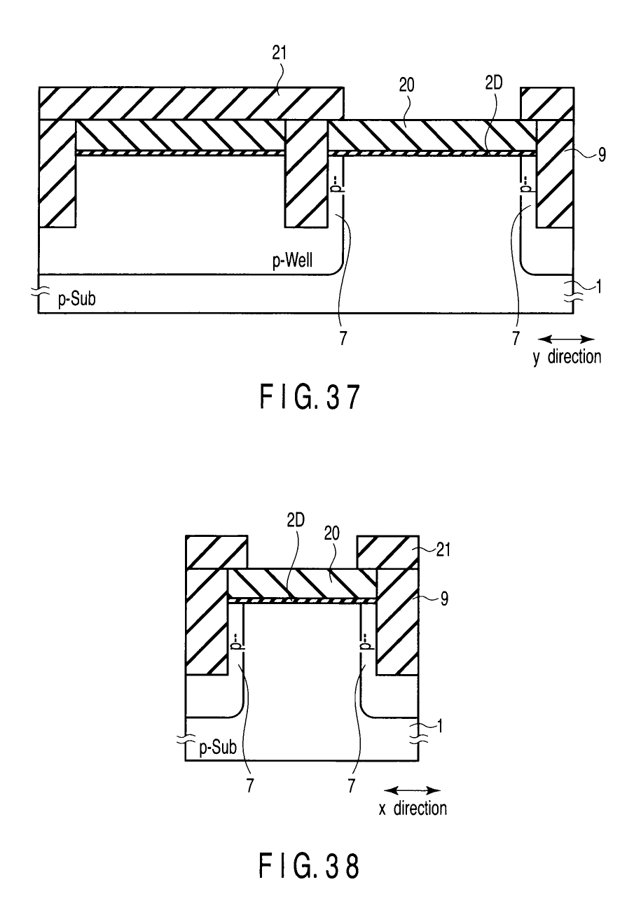

Subsequently, a step following that shown in FIGS. 35 and 36 will now be explained with reference to FIGS. 37 and 38. FIG. 37 is a cross-sectional view along the y-direction of the peripheral transistor region, and FIG. 38 is a cross-sectional view along the x-direction of the peripheral transistor region.

As shown in FIGS. 37 and 38, a resist mask 21 is formed to cover an entire surface above the low-breakdown-voltage transistor MIS transistor region. Additionally, in the high-breakdown-voltage MIS transistor region, the resist mask 21 is formed to cover a boundary portion between the semiconductor substrate 1 and the element isolation insulating film 9. Further, an n-type impurity is ion-implanted so that the high-breakdown-voltage MIS transistor region becomes an intrinsic region.

Here, since the ions are not implanted into the low-breakdown-voltage MIS transistor region covered with the resist mask 21, the well region p-Well remains, and this becomes an active region for the low-breakdown-voltage MIS transistor.

Furthermore, in the high-breakdown-voltage MIS transistor region, the ions are not implanted into a position near the boundary between the semiconductor substrate 1 and the element isolation insulating film 9 covered with the resist mask 21. Therefore, a region containing the p-type impurity remains at the boundary portion between the semiconductor substrate 1 and the element isolation insulating film 9, and this becomes an impurity layer 7 that is provided in the semiconductor substrate 1 along a side surface of the element isolation insulating film 9.

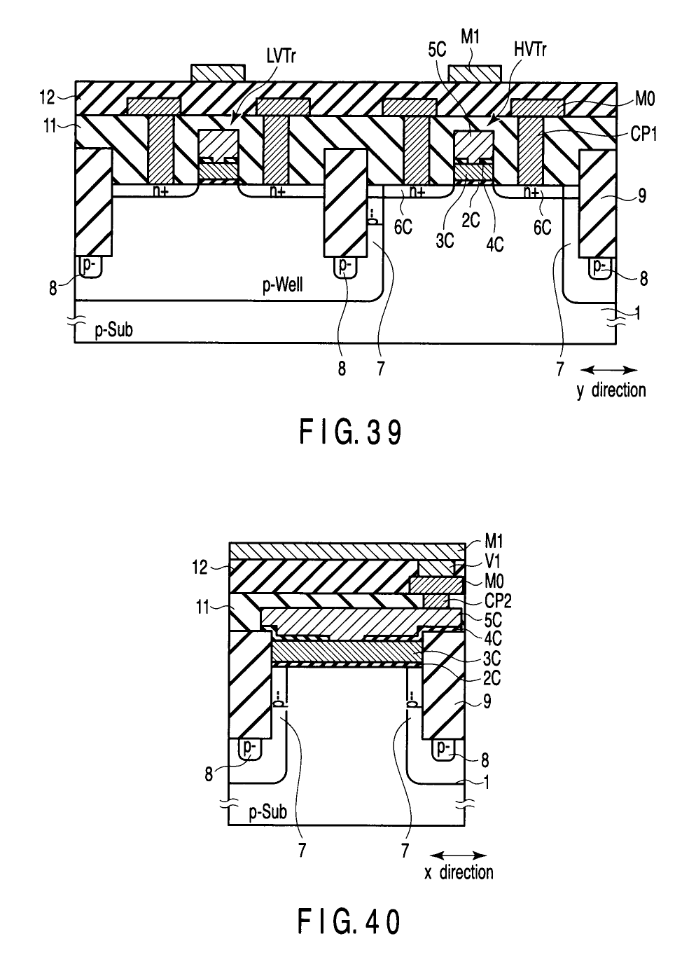

Then, after the resist mask 21, the dummy layer 20, and the dummy insulating film 2D are removed, an impurity layer 8 is formed in the semiconductor substrate 1 along a bottom surface of the element isolation insulating film 9 at the same step as those in the first and second examples as shown in FIGS. 39 and 40.

Moreover, a gate insulating film, a first gate electrode material, an inter-gate insulating film, and a second gate electrode material are sequentially formed on the semiconductor substrate 1. Additionally, gate processing is carried out at the same steps as those shown in FIGS. 5 to 10 in the first example, thereby forming diffusion layers 6C which become a source and a drain. Thereafter, inter-layer insulating films 11 and 12, contact plugs CP1 and CP2, and metal layers M0 and M1 are sequentially formed.

With the above-explained steps, the peripheral transistor according to this example is formed.

According to this example, in the high-breakdown-voltage MIS transistor forming region (the active region AA-H), the first impurity layer 7 is formed in the semiconductor substrate 1 along the side surface of the element isolation insulating film 9. Additionally, this impurity layer 7 is formed simultaneously with the P well region P-well of the low-breakdown-voltage MIS transistor region.

In this example, likewise, even when the organic substance contained in the element isolation insulating film 9 is diffused into the semiconductor substrate 1 to form the fixed charge trap, the impurity layer 7 formed along the side surface of the element isolation insulating film 9 can alleviate an influence of the fixed charge trap. Therefore, it is possible to provide a nonvolatile semiconductor memory in which degradation of driving characteristics of the peripheral transistor caused by the fixed charge trap, especially an inverse narrow channel effect of the high-breakdown-voltage MIS transistor is suppressed.

It is to be noted that the P well region P-well has the function as the channel stopper, and hence the impurity layer 8 does not have to be provided in this example.

### (2) Second Embodiment

### (A) BASIC STRUCTURE

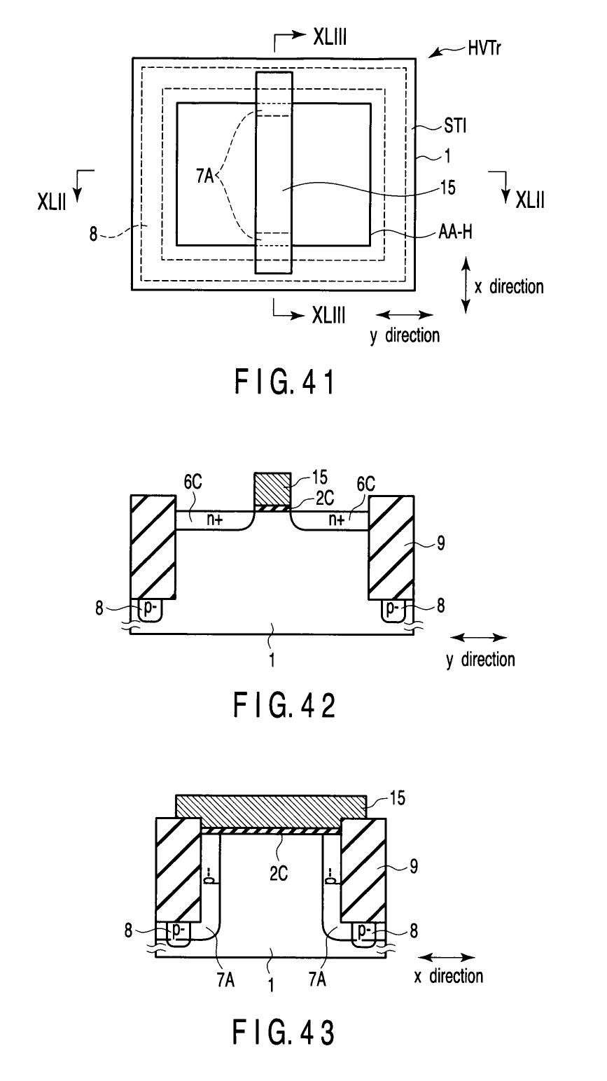

A second embodiment according to the present invention will now be explained with reference to FIGS. 41 to 43. It is to be noted that like reference numbers denote members equal to those in the first embodiment, thereby omitting a detailed explanation thereof.

FIG. 41 is a plan view of a high-breakdown-voltage MIS transistor according to this embodiment. FIG. 42 is a cross-sectional view taken along line XLII-XLII in FIG. 41, and FIG. 43 is a cross-sectional view taken along line XLIII-XLIII in FIG. 41.

In the first embodiment according to the present invention, the impurity layer is provided in the semiconductor substrate to surround the entire active region along the side surface of the element isolation insulating film in order to suppress the inverse narrow channel effect caused by the fixed charge trap.

However, the inverse narrow channel effect is caused by the fixed charge trap formed between the two diffusion layers 6C that become the source and the drain of the high-breakdown-voltage MIS transistor, i.e., in the channel region. Therefore, the impurity layer 7 does not have to be provided at the entire boundary portion between the active region AA-H and the element isolation insulating film 9.

In this embodiment, as shown in FIGS. 41 to 43, an impurity layer 7A that suppresses an influence of the fixed charge trap is provided at both end portions in a channel region adjacent to an element isolation insulating film 9 in a channel width direction along a side surface of the element isolation insulating film 9.

Therefore, in this embodiment, as in the first embodiment, it is possible to suppress degradation of driving characteristics of a peripheral transistor caused by the fixed charge trap, especially the inverse narrow channel effect of the high-breakdown-voltage MIS transistor provided in an intrinsic region.

### (B) EXAMPLE

(a) Structure

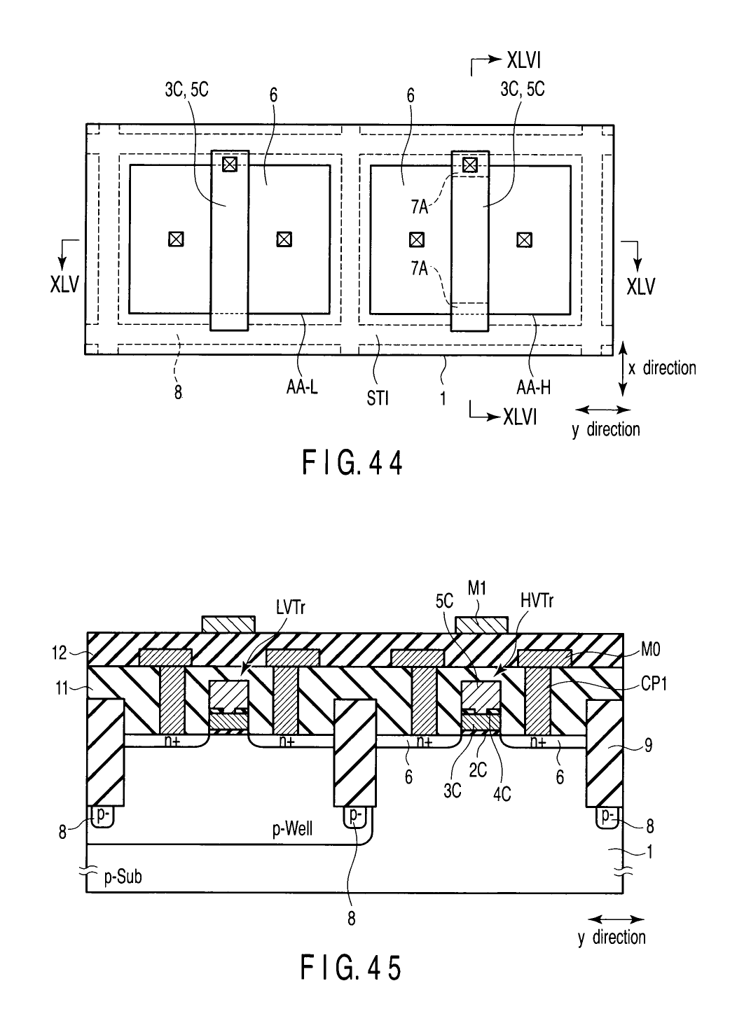

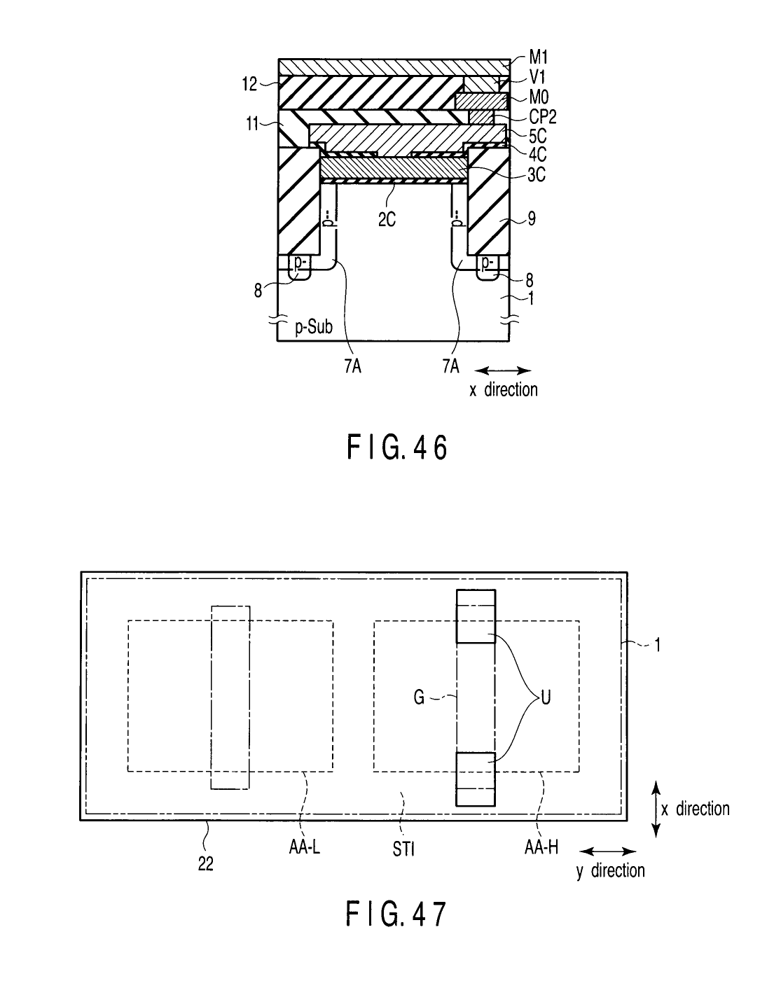

An example of this embodiment will now be explained with reference to FIGS. 44 to 46. Like reference numbers denote members equal to those in the first embodiment, thereby omitting a detailed explanation thereof. Further, a structure of a memory cell region is the same as that shown in FIGS. 5 to 7 of the first embodiment, thus omitting a detailed description thereof.

As shown in FIGS. 44 to 46, in this embodiment, likewise, a high-breakdown-voltage MIS transistor HVTr is an MIS transistor having a stacked gate structure.

The impurity layer 7A that suppresses the influence of the fixed charge trap is provided in the semiconductor substrate at both end portions in the channel width direction between the two diffusion layers 6C (the channel region) that become the source and the drain along the side surface of the element isolation insulating film 9. When the element isolation insulating film 9 is formed of an insulating material containing an organic substance, providing this first impurity layer 7 enables alleviating the influence of the fixed charge trap caused by the organic substance.

Furthermore, providing the impurity layer 7A results in an increase in a substrate impurity concentration in an active region (intrinsic region) AA-H of the high-breakdown-voltage MIS transistor HVTr. Therefore, in the high-breakdown-voltage MIS transistor, a substrate bias effect determined based on the substrate impurity concentration can be improved. Moreover, according to this embodiment, a size of the first impurity layer 7A becomes smaller than that in the first embodiment. Accordingly, a junction leak between the first impurity layer 7A and the semiconductor substrate 1 (the intrinsic region) can be reduced.

As explained above, it is possible to suppress degradation of driving characteristics of the peripheral transistor caused by the fixed charge trap in the channel region, especially the inverse narrow channel effect of the high-breakdown-voltage MIS transistor provided in the intrinsic region.

(b) Manufacturing Method

The structure of the peripheral transistor according to this example depicted in FIGS. 44 to 46 can be formed by using the same manufacturing method as that shown in FIGS. 5 to 40 of the first embodiment.

However, when the impurity layer 7A is formed based on the ion implantation method like the step shown in FIGS. 17 and 18 of the first embodiment, a resist mask 22 that covers an upper side of the semiconductor substrate 1 is formed in the high-breakdown-voltage MIS transistor region as shown in FIG. 47. In this resist mask 22, opening portions U are formed at end portions of a gate electrode formation planned region G indicated by an alternate long and short dash line along the channel width direction. This resist mask 22 is used as a mask to execute the ion implantation method, thereby forming the impurity layer 7A.

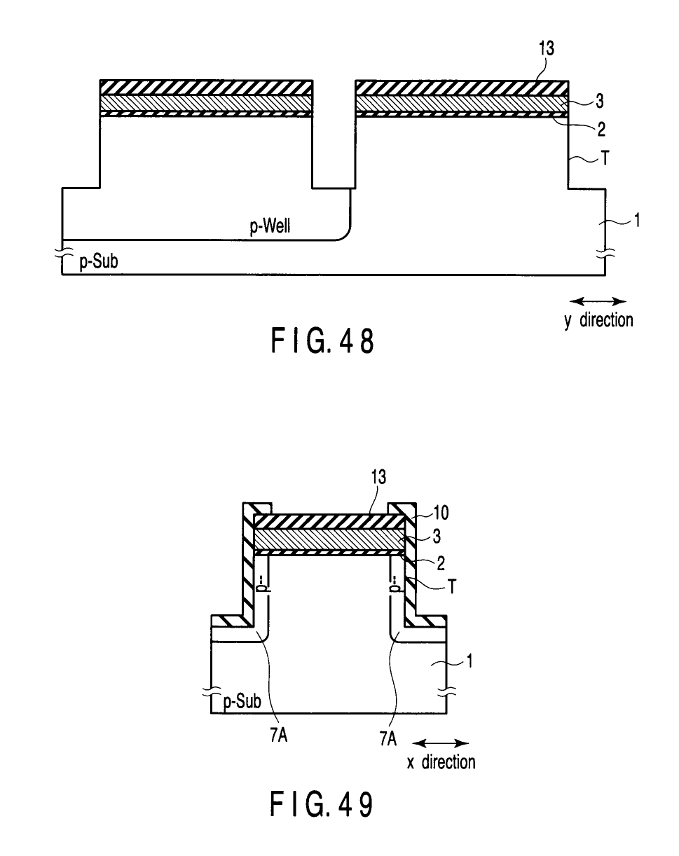

Moreover, when the impurity layer 7A is formed based on the solid-phase diffusion method like the step shown in FIGS. 19 to 22 of the first embodiment, a solid-phase diffusion source (e.g., BSG) 10 is formed on a side surface alone of an element isolation trench T which is placed in the channel width direction of the gate electrode formation planned region in the high-breakdown-voltage MIS transistor region as depicted in FIGS. 48 and 49. Additionally, a p-type impurity (boron (B)) contained in this solid-phase diffusion source 10 is thermally diffused, thus forming the impurity layer 7A in the semiconductor substrate.

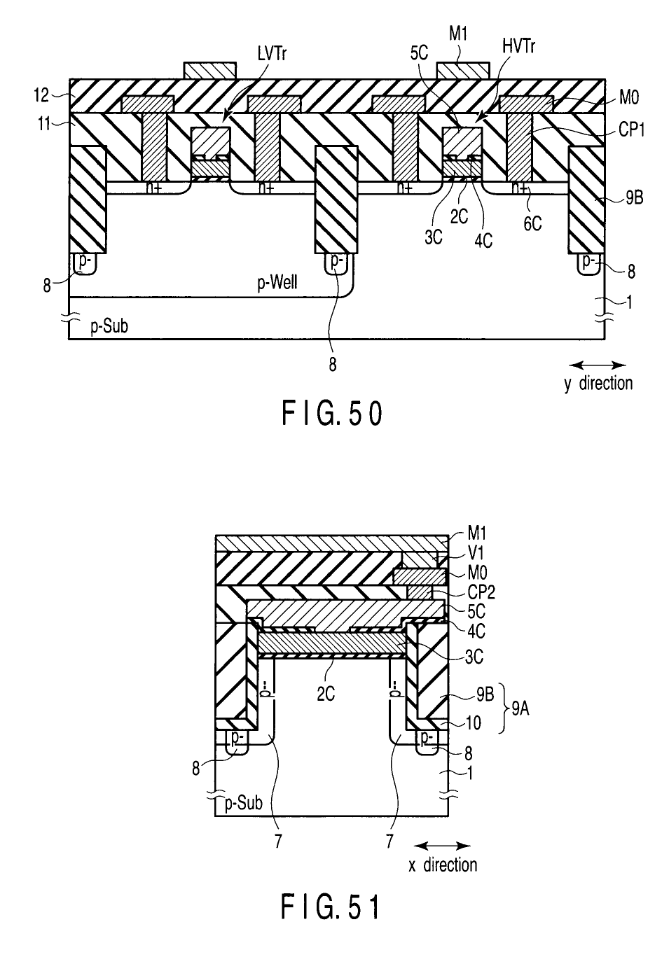

It is to be noted that, as in the second example of the first embodiment, the solid-phase diffusion source 10 and an insulating film containing an organic substance may form an element isolation insulating film without removing the solid-phase diffusion source 10. In this case, a structure shown in FIGS. 50 and 51 can be obtained, and an element isolation insulating film 9A is formed of an insulating film 9B containing an organic substance and an insulating film 10 that becomes the solid-phase diffusion source in a cross-sectional structure in the channel width direction.

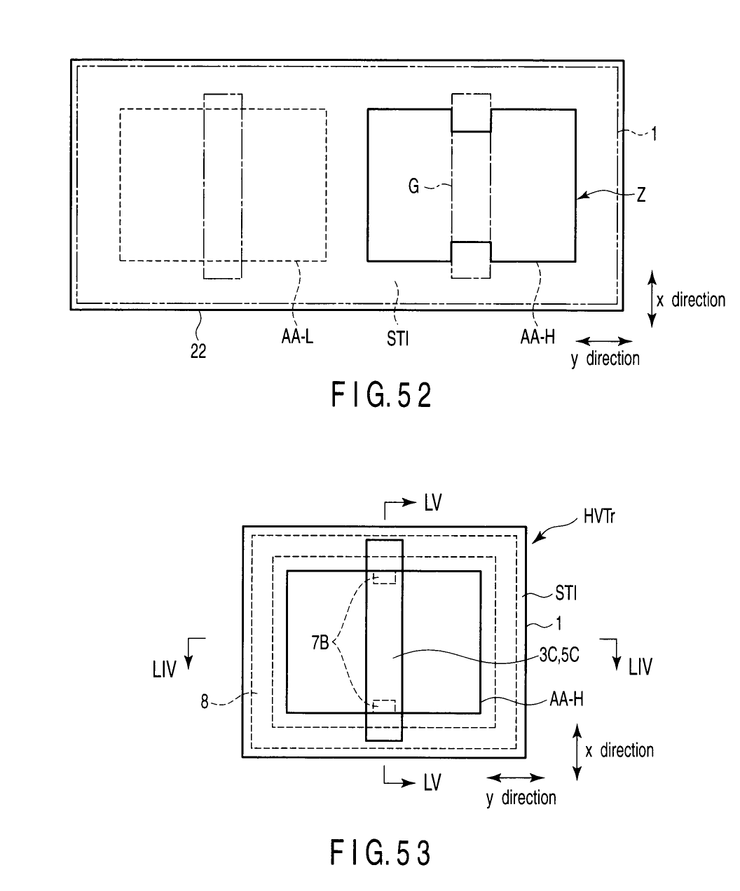

Further, as in the third example of the first embodiment, when the first impurity layer 7A is formed simultaneously with a p well region in which an n-channel low-breakdown-voltage MIS transistor is provided, the resist mask 22 is formed on the semiconductor substrate 1 as depicted in FIG. 52. At this time, in the high-breakdown-voltage MIS transistor region, an opening portion Z is formed in the resist 22 in such a manner that end portions of the gate formation planned region G in the channel width direction are covered with the resist mask 22. As a result, even when ion implantation is carried out to form the high-breakdown-voltage MIS transistor region as the intrinsic region, the impurity layer 7A remains at both end portions in the channel region in the channel width direction.

As explained above, according to the manufacturing method of this embodiment, in the high-breakdown-voltage MIS transistor region (the active region AA-H), the first impurity layer 7A can be formed in the semiconductor substrate 1 at both the end portions in the channel region in the channel width direction along the side surface of the element isolation insulating film 9. Therefore, even when the organic substance contained in the element isolation insulating film 9 is diffused into the semiconductor substrate to form the fixed charge trap, the impurity layer 7A formed along the side surface of the element isolation insulating film 9 enables alleviating an influence of the fixed charge trap.

Furthermore, according to this embodiment, the size of the impurity layer 7A becomes smaller than that in the first embodiment. Therefore, it is possible to provide a nonvolatile semiconductor memory in which a junction leak between the impurity layer 7A and the semiconductor substrate 1 (the intrinsic region) is reduced in the high-breakdown-voltage MIS transistor.

As explained above, it is possible to provide a nonvolatile semiconductor memory in which degradation of driving characteristics of the peripheral transistor caused by the fixed charge trap, especially the inverse narrow channel effect of the high-breakdown-voltage MIS transistor.

### (3) Third Embodiment

### (A) BASIC STRUCTURE

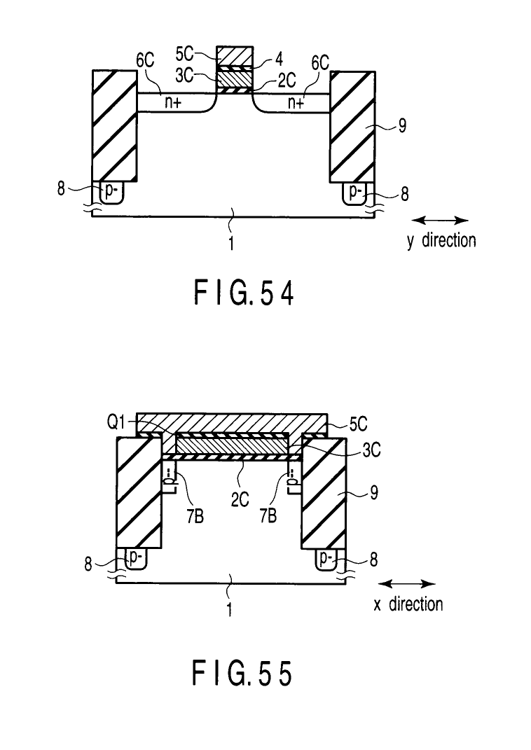

A basic structure of a third embodiment according to the present invention will now be explained with reference to FIGS. 53 to 55. It is to be noted that, in this embodiment, structures of each memory cell and each select gate transistor in a memory cell region are equal to those in the first embodiment, thereby omitting an explanation thereof. FIG. 53 is a plan view showing a high-breakdown-voltage MIS transistor according to this embodiment. FIG. 54 is a cross-sectional view taken along line LIV-LIV in FIG. 53, and FIG. 55 is a cross-sectional view taken along line LV-LV in FIG. 53.

As in each example of the first and second embodiments, since a peripheral transistor used in a flash memory is formed simultaneously with formation of each memory cell, the peripheral transistor becomes an MIS transistor having a stacked gate structure. Therefore, as shown in FIGS. 53 to 55, a first gate electrode 3C which is formed simultaneously with a floating gate electrode of a memory cell is arranged on a gate insulating film 2C provided on a channel region surface. Further, a second gate electrode 5C is laminated on the first gate electrode 3C through an inter-gate insulating film 4C. This second gate electrode 5C is connected with the first gate electrode 3C through each opening portion Q1 formed in the inter-gate insulating film 4C.

In this embodiment, the opening portion Q1 formed in the inter-gate insulating film 4C is formed at each end portion in a channel width direction. The second gate electrode 5C is connected with a side surface of the first gate electrode 3C in the channel width direction through this opening portion Q1. Furthermore, an impurity layer 7B that suppresses an influence of a fixed charge trap is provided at both end portions in the channel width direction in the channel region along a side surface of an element isolation insulating film 9.

Therefore, in this embodiment, as in the first and second embodiments, the inverse narrow channel effect of the high-breakdown-voltage MIS transistor provided in an intrinsic region can be suppressed.

It is to be noted that, when the impurity layer 7B that suppresses the fixed charge trap is formed at the end portions along the channel width direction in the channel region at a manufacturing step for the above-explained structure, the impurity layer 7B can be formed in a self-aligning manner with respect to the opening portion formed in the first gate electrode.

### (B) EXAMPLE

(a) Structure

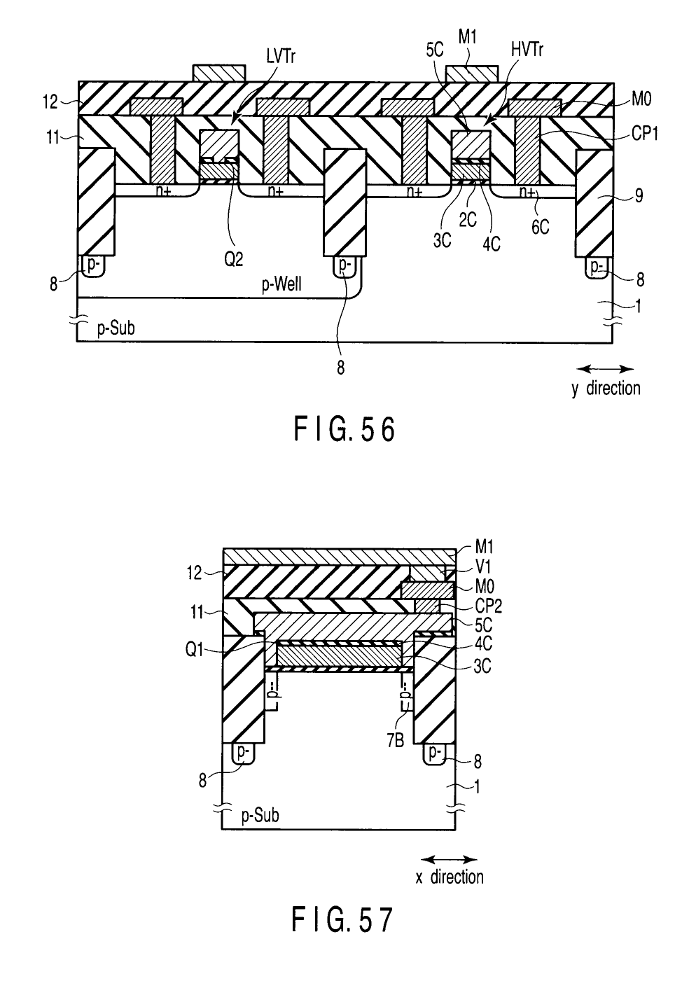

An example of this embodiment will now be explained with reference to FIGS. 56 and 57. It is to be noted that like reference numbers denote members equal to those in the first embodiment, thereby omitting a detailed explanation thereof. Furthermore, since a structure of the memory cell region is the same as that shown in FIGS. 5 to 7 of the first embodiment, thereby omitting a detailed explanation thereof.

As shown in FIGS. 56 and 57, the high-breakdown-voltage MIS transistor HVTr is an MIS transistor having a stacked gate structure. The first gate electrode 3C is arranged on the gate insulating film 2C formed on the channel region surface. The size of the first gate electrode 3C in the channel width direction is smaller than that of a channel width of the channel region.

The inter-gate insulating film 4C is provided on the first gate electrode 3C. The opening portion Q1 is formed at each of both end portions of the inter-gate insulating film 4C in the channel width direction. Further, the second gate electrode 5C is provided on the inter-gate insulating film 4C, and the gate electrode 5C is connected with both side surfaces of the first gate electrode 3C in the channel width direction through the opening portions Q1.

The impurity layer 7B that suppresses an influence of the fixed charge trap is provided in the semiconductor substrate 1 along the side surface of the element isolation insulating film 9 at each end portion in the channel region in the channel width direction. When the element isolation insulating film 9 is formed of an insulator containing an organic substance, providing the first impurity layer 7B enables alleviating the influence of the fixed charge trap caused by this organic substance.

Furthermore, when the impurity layer 7B is provided, a substrate impurity concentration in an active region (intrinsic region) AA-H where the high-breakdown-voltage MIS transistor HVTr is provided is increased. Therefore, a substrate bias effect of the MIS transistor which is determined based on the substrate impurity concentration can be improved. Moreover, according to this embodiment, a size of the impurity layer 7B becomes smaller than that in the first embodiment. Accordingly, a junction leak between the impurity layer 7B and the semiconductor substrate 1 (the intrinsic region) can be reduced.

As explained above, it is possible to suppress degradation of driving characteristics of a peripheral transistor caused by the fixed charge trap in the channel region, especially the inverse narrow channel effect of the high-breakdown-voltage MIS transistor provided in the intrinsic region.

(b) Manufacturing Method

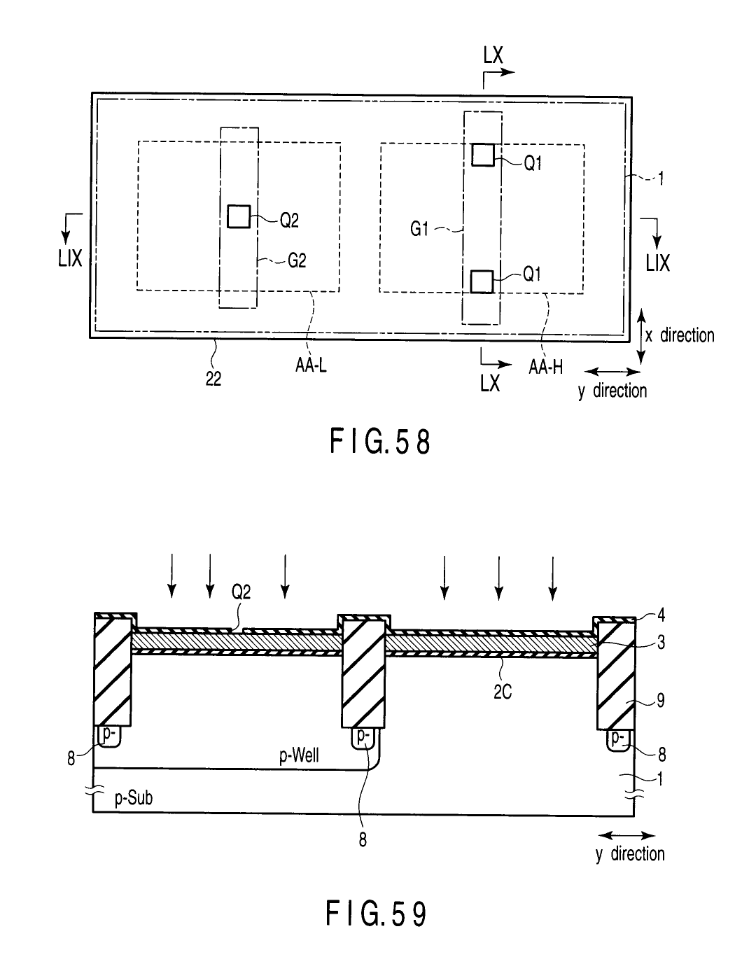

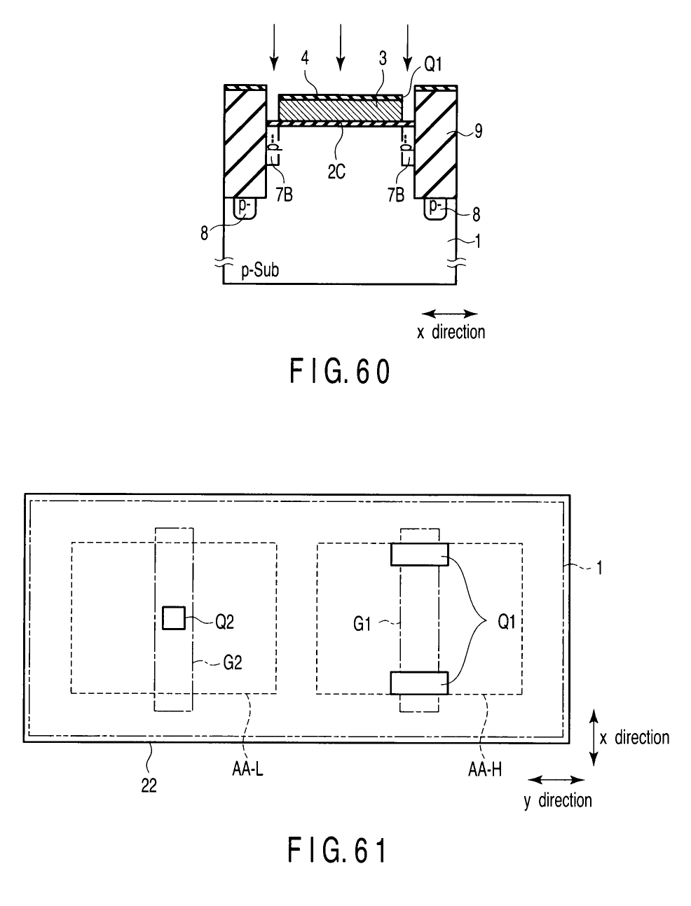

A manufacturing method according to this example will now be explained with reference to FIGS. 58 to 61. FIGS. 58 and 61 are plan views of the high-breakdown-voltage MIS transistor according to this embodiment. FIG. 59 is a cross-sectional view taken along line LIX-LIX in FIG. 58, and FIG. 60 is a cross-sectional view taken along line LX-LX in FIG. 58.

First, a gate insulating film 2, a polysilicon film 3 that becomes a first gate electrode, and a mask film 13 are sequentially formed on a surface of the semiconductor substrate 1 at the same manufacturing steps as those in the first embodiment shown in FIGS. 11 to 14. Then, each element isolation trench T having an STI structure if formed based on, e.g., the RIE method, and the element isolation insulating film 9 using polysilazane is buried in the element isolation trench T based on a coating method.

Subsequently, after removing the mask film 13, as shown in FIGS. 58 to 61, opening portions Q1 and Q2 through which the first gate electrode is connected with the second gate electrode are formed in an inter-gate insulating film 4 using a resist mask 22 as shown in FIGS. 58 or 61. At this time, in a low-breakdown-voltage MIS transistor forming region AA-L, the opening portion Q2 is formed at a central portion of a gate formation planned region G2, for example. On the other hand, in the high-breakdown-voltage MIS transistor forming region AA-H, the opening portions Q1 are formed at both end portions in a channel region of a gate formation planned region G1.

Moreover, in the high-breakdown-voltage MIS transistor region AA-H, a first gate electrode material 3 is etched based on the RIE method, and a size of the first gate electrode material 3 in the channel width direction is reduced to be smaller than a size of the channel width of the high-breakdown-voltage MIS transistor. Then, the impurity layer 7B is formed in the semiconductor substrate 1 in a self-aligning manner with respect to the opening portions Q1 formed in the polysilicon film 3 and the inter-gate insulating film 4 based on the ion implantation method.

Thereafter, a second gate electrode material 5 is formed at the same step as that of the first embodiment shown in FIGS. 27 to 30. Additionally, the second gate electrode material 5C is connected with the first gate electrode material 3 through the opening portions Q1 formed in the inter-gate insulating film 4.

Further, gate processing is carried out at the same steps as those shown in FIGS. 5 to 10, and then diffusion layers 6C that become a source and a drain are formed. Subsequently, interlayer insulating films 11 and 12, contact plugs CP1 and CP2, and metal layers M0 and M1 are sequentially formed.

With the above-explained manufacturing steps, the peripheral transistor according to this example is formed.

As explained above, according to the manufacturing method according to this embodiment, the gate structure of the high-breakdown-voltage MIS transistor is a structure where the second gate electrode 5C is connected with the side surface of the first gate electrode 3C in the channel width direction through the opening portion Q2 formed in the inter-gate insulating film 4C.

Furthermore, in the high-breakdown-voltage MIS transistor region AA-H, the first impurity layer 7B can be formed in the semiconductor substrate 1 at both end portions in the channel region along the side surface of the element isolation insulating film 9 in a self-aligning manner with respect to the opening portions formed in the inter-gate insulating film 4C and the first gate electrode 3C.

Therefore, even when the organic substance contained in the element isolation insulating film 9 is diffused into the semiconductor substrate to form the fixed charge trap, the impurity layer 7B formed along the side surface of the element isolation insulating film 9 enables alleviating the influence of the fixed charge trap. Moreover, according to this embodiment, the size of the impurity layer 7B becomes smaller than that in the first embodiment. Therefore, in the high-breakdown-voltage MIS transistor, it is possible to provide a nonvolatile semiconductor memory in which a junction leak between the impurity layer 7B and the semiconductor substrate 1 (the intrinsic region) is reduced.

Additionally, in this example, since the first impurity layer 7B is formed through the opening portions Q1 formed to electrically connect the first gate electrode material with the second gate electrode material in the high-breakdown-voltage MIS transistor based on the ion implantation method, the number of the manufacturing steps can be reduced as compared with a case where the opening portions are separately formed.

As explained above, it is possible to provide the nonvolatile semiconductor memory in which degradation of driving characteristics of the peripheral transistor caused by the fixed charge trap, especially the inverse narrow channel effect of the high-breakdown-voltage MIS transistor is suppressed.

### (4) Fourth Embodiment

### (a) Structure

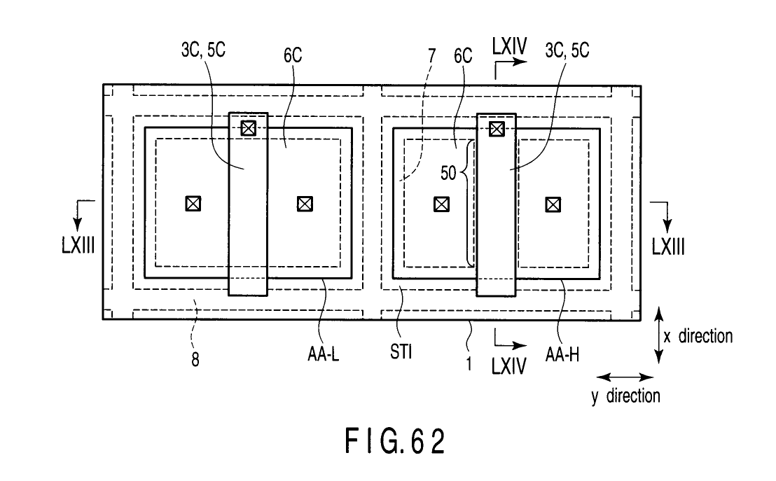

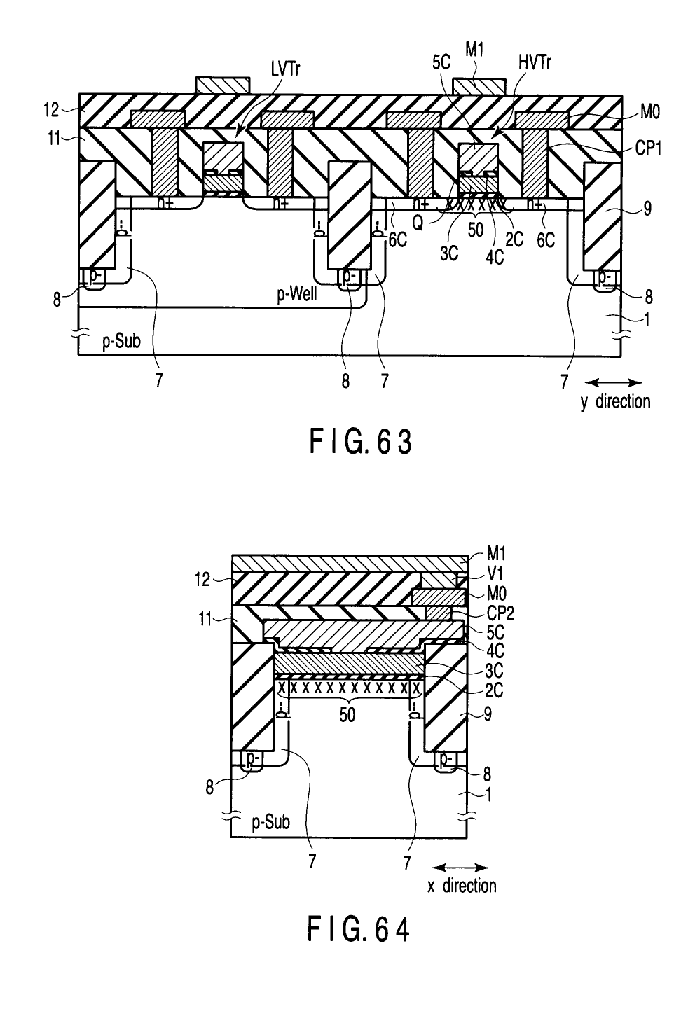

A fourth embodiment according to the present invention will now be explained with reference to FIGS. 62 to 66. It is to be noted that since structures of each memory cell and each select gate transistor in a memory cell region in this embodiment are equal to those in the first embodiment, thereby omitting an explanation thereof. FIG. 62 is a plan view showing a high-breakdown-voltage MIS transistor according to this embodiment. FIG. 63 is a cross-sectional view taken along line LXIII-LXIII in FIG. 62, and FIG. 64 is a cross-sectional view taken along line LXIV-LXIV in FIG. 62.

In the fourth embodiment according to the present invention, an n-channel enhancement-type high-breakdown-voltage MIS transistor is used as the high-breakdown-voltage MIS transistor. As shown in FIGS. 62 to 64, in the n-channel enhancement-type high-breakdown-voltage MIS transistor, a p-type impurity such as boron (B) that is equal to that used in formation of a first impurity layer 7 is ion-implanted into a surface layer of a semiconductor substrate 1 in a channel region of this transistor to form a channel concentration control region 50 for profile control over a channel concentration for a reduction in channel length. In this embodiment, attention is paid to this point, and the channel concentration control region 50 and the first impurity layer 7 are simultaneously formed.

(b) Manufacturing Method

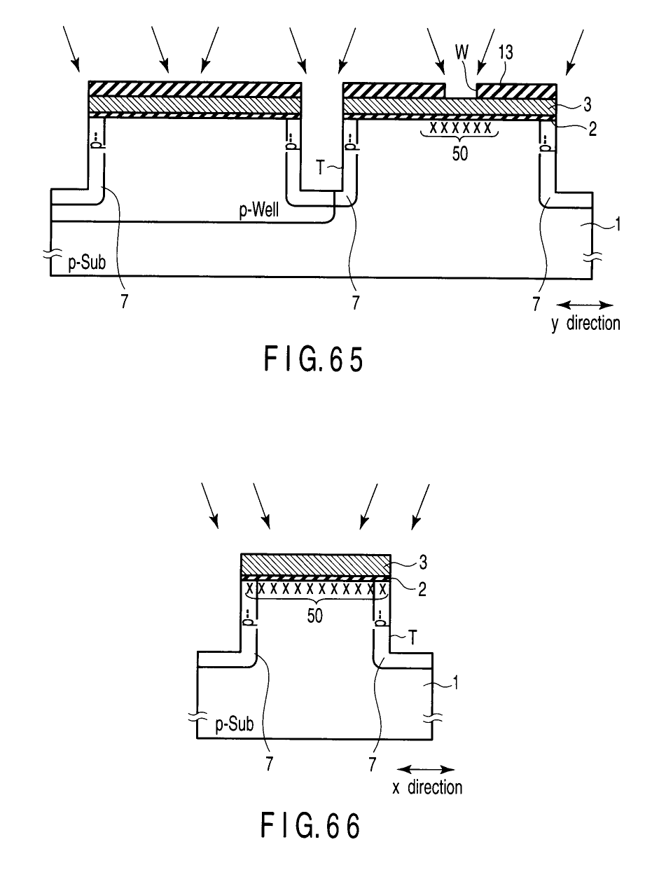

A manufacturing method according to this embodiment will now be explained with reference to FIGS. 65 to 66. FIG. 65 is a cross-sectional view taken along line LXIII-LXIII in FIG. 62, and FIG. 66 is a cross-sectional view taken along line LXIV-LXIV in FIG. 62.

In this embodiment, as shown in FIGS. 65 and 66, a mask film 13 in a channel forming region of the high-breakdown-voltage MIS transistor is etched to be removed based on the RIE method after forming each element isolation trench T, and the p-type impurity is ion-implanted into the semiconductor substrate 1 while using the mask film 13 as a mask in place of the step of forming the impurity layer 7 in the first embodiment depicted in FIGS. 17 and 18.

That is, after forming each element isolation trench T shown in FIGS. 13 and 14, a resist (not shown) is applied to an upper side of the mask film 13. Then, the resist is patterned to remove the resist at a portion corresponding to the channel forming region of the high-breakdown-voltage MIS transistor. Subsequently, the mask film 13 is etched to be removed based on the RIE method while using the patterned resist as a mask, thereby forming an opening portion W depicted in FIG. 65. Subsequently, the resist mask is delaminated, and the p-type impurity is ion-implanted into the channel forming region of the high-breakdown-voltage MIS transistor through the element isolation trench T and the opening portion W while using the mask film 13 as a mask.

This method enables simultaneously forming the channel concentration control region 50 and the first impurity layer 7 in the n-channel enhancement-type high-breakdown-voltage MIS transistor, thus reducing the number of the manufacturing steps.

Thereafter, as in the first embodiment, each element isolation trench T is filled with an element isolation insulating film 9, and stacked gate electrodes 3C and 5C and source/drain diffusion layers 6C of a peripheral transistor are sequentially formed, thus constituting the peripheral transistor.

As explained above, according to the manufacturing method of this embodiment, in the high-breakdown-voltage MIS transistor region (active region AA-H), the channel concentration control region 50 can be formed in the channel region, and the first impurity layer 7 can be formed in the semiconductor substrate 1 along a side surface of the element isolation insulating film 9.

Therefore, even when an organic substrate contained in the element isolation insulating film 9 is diffused into the semiconductor substrate to form the fixed charge trap, the impurity layer 7 formed along the side surface of the element isolation insulating film 9 enables alleviating the influence of the fixed charge trap. Additionally, simultaneously forming the channel concentration control region 50 and the first impurity layer 7 of the high-breakdown-voltage MIS transistor enables reducing the number of the manufacturing steps.

As explained above, it is possible to provide a nonvolatile semiconductor memory in which degradation of driving characteristics of the peripheral transistor caused by the fixed charge trap, especially the inverse narrow channel effect of the high-breakdown-voltage MIS transistor is suppressed.

### 2. Others

In the embodiments according to the present invention, the description has been given as to the peripheral transistor used in the nonvolatile semiconductor memory (the flash memory) as the example. However, the embodiments according to the present invention are not restricted thereto, and they may be used for, e.g., a peripheral transistor of a semiconductor memory, e.g., a static random access memory (SRAM) or a dynamic random access memory (DRAM).

Further, in the embodiments according to the present invention, the description has been given as to the example where the first gate electrode material is formed and then the element isolation insulating trench T is formed. However, the embodiments according to the present invention are not restricted to thereto, and a manufacturing method of first forming the element isolation trench and then forming the gate electrode material can be adopted.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory comprising:
a first element isolation insulating film containing an organic substance which surrounds a first region;
a memory cell arranged in the first region;
a second element isolation insulating film containing an organic substrate which surrounds a second region;
a peripheral transistor arranged in the second region; and
a first impurity layer which is provided in the semiconductor substrate along a side surface of the second element isolation insulating film.

2. The nonvolatile semiconductor memory according to claim 1, wherein the peripheral transistor has:
first and second diffusion layers provided in the semiconductor substrate,
a gate insulating film provided on a channel region surface between the first and second diffusion layers, and
a gate electrode arranged on the gate insulating film; and
the first impurity layer is provided along the side surface alone of the second element isolation insulating film at end portions in the channel region in a channel width direction.

3. The nonvolatile semiconductor memory according to claim 1, wherein the semiconductor substrate and the first impurity layer have the same conductivity type.

4. The nonvolatile semiconductor memory according to claim 1, further comprising:
a second impurity layer which is provided in the semiconductor substrate along a bottom surface of the second element isolation insulating film.

5. The nonvolatile semiconductor memory according to claim 4, wherein an impurity concentration of the first impurity layer is lower than an impurity concentration of the second impurity layer.

6. The nonvolatile semiconductor memory according to claim 1, wherein the second element isolation insulating film is formed of a first insulating film containing an organic substance and a second insulating film provided between the first insulating film and the semiconductor substrate.

7. The nonvolatile semiconductor memory according to claim 6, wherein the second insulating film contains the same impurity as that in the first impurity layer.

8. The nonvolatile semiconductor memory according to claim 2, wherein the gate electrode has:
a first gate electrode layer provided on the gate insulating film;
an inter-gate insulating film which is provided on the first gate electrode layer and has an opening portion; and
a second gate electrode layer which is provided on the inter-gate insulating film and in contact with the first gate electrode layer through the opening portion.

9. The nonvolatile semiconductor memory according to claim 8, wherein the opening portion is provided at an end portion of the inter-gate insulating film in the channel width direction.

10. The nonvolatile semiconductor memory according to claim 9, wherein a dimension of the first gate electrode layer in the channel width direction is smaller than a dimension of the second gate electrode layer in the channel width direction.

11. The nonvolatile semiconductor memory according to claim 1, further comprising:
an impurity region which is provided in a channel region of the peripheral transistor and has the same conductivity type as does the first impurity layer.

12. The nonvolatile semiconductor memory according to claim 1, wherein the peripheral transistor is a high-breakdown-voltage MIS transistor.

13. A method of manufacturing a nonvolatile semiconductor memory comprising:
forming an element isolation trench in a semiconductor substrate to form an element forming region surrounded by the element isolation trench;
forming an impurity layer in the semiconductor substrate along a side surface of the element isolation trench;
forming an element isolation insulating film containing an organic substrate in the element isolation trench; and
forming a peripheral transistor in the element forming region.

14. The method of manufacturing a nonvolatile semiconductor memory according to claim 13, wherein the element isolation insulating film is formed by:
applying an insulating material containing an organic substance to the inside of the element isolation trench; and
performing a heat treatment with respect to the applied insulating material.

15. The method of manufacturing a nonvolatile semiconductor memory according to claim 13, wherein the impurity layer is formed based on a solid-phase diffusion method.

16. The method of manufacturing a nonvolatile semiconductor memory according to claim 13, further comprising:
simultaneously implanting an impurity into a channel forming region of the peripheral transistor when forming the impurity layer in the semiconductor substrate.

17. A method of manufacturing a nonvolatile semiconductor memory comprising:
forming a first gate electrode material on a gate insulating film on a semiconductor substrate surface;
forming a mask film on the first gate electrode material and patterning the mask film;
etching the first gate electrode material and the semiconductor substrate while using the patterned mask film as a mask, and forming an element isolation trench in the semiconductor substrate to form an element forming region surrounded by the element isolation trench;
forming an element isolation insulating film containing an organic substance in the element isolation insulating trench;
forming an inter-gate insulating film on the first gate electrode material;
forming an opening portion at a position of the inter-gate insulating film which is adjacent to the element isolation insulating film;
etching the first gate electrode material through the opening portion to expose the gate insulating film;
forming an impurity layer in the semiconductor substrate along a side surface of the element isolation insulating trench in a self-aligning manner with respect to the opening portion;
forming a second gate electrode material on the gate insulating film exposed through the opening portion and the inter-gate insulating film to connect the second gate electrode material with the first gate electrode material;
performing gate processing with respect to the first and second gate electrode materials; and
forming first and second diffusion layers in the element forming region.

18. The method of manufacturing a nonvolatile semiconductor memory according to claim 17, wherein the element isolation insulating film is formed by:
applying an insulating material containing an organic substance to the inside of the element isolation trench; and
performing a heat treatment with respect to the applied insulating material.

19. A method of manufacturing a nonvolatile semiconductor memory having a high-breakdown-voltage transistor comprising:
forming a first gate electrode material on a gate insulating film on a semiconductor substrate surface;
forming a mask film on the first gage electrode material and patterning the mask film;
etching the first gate electrode material and the semiconductor substrate while using the patterned mask film as a mask to form an element isolation trench in the semiconductor substrate, thereby forming an element forming region surrounded by the element isolation trench;
removing the mask film at a portion in the element forming region corresponding to a channel region of the high-breakdown-voltage transistor;
forming an impurity layer in the semiconductor substrate along the channel region of the high-breakdown-voltage transistor and a side surface of the element isolation trench while using as a mask the mask film removed at the portion corresponding to the channel region; and
forming an element isolation insulating film containing an organic substance in the element isolation trench.

20. The method of manufacturing a nonvolatile semiconductor memory having a high-breakdown-voltage transistor according to claim 19, wherein forming the element isolation insulating film has:
applying an insulating film containing an organic substance to the inside of the element isolation trench; and
performing a heat treatment with respect to the applied insulating material.
